(19) United States
(12) Patent Application Publication
(10) Pub. No.: US 2016/0008784 A1
(43) Pub. Date: Jan. 14, 2016

(54) TEMPERATURE MANAGEMENT IN CHLORINATION PROCESSES AND SYSTEMS RELATED THERETO

(71) Applicant: SITEC GMBH, Augsburg (DE)

(72) Inventor: Mark William Dassel, Poulsbo, WA (US)

(21) Appl. No.: 14/771,200

(22) PCT Filed: Mar. 12, 2014
(86) PCT No.: PCT/US2014/024620

§ 371 Date: Aug. 27, 2015

Related U.S. Application Data
(60) Provisional application No. 61/779,613, filed on Mar. 13, 2013.

(51) Int. Cl. B01J 19/00; C23C 16/448; C23C 16/24; C01B 33/107

(52) U.S. Cl. CPC B01J 19/0013; C01B 33/10763; C23C 16/4488; C23C 16/24; B01J 2219/00123

(57) ABSTRACT

Reactor design and operating conditions enabling adiabatic direct chlorination of metallurgic silicon by hydrogen chloride are presented. The exothermic heat of reaction is absorbed by cooling fluid in admixture with the reactants and products of the reaction, thereby eliminating the necessity of external cooling for the reactor. Reactor temperature is managed by controlling the temperature and composition of reactor feedstock. Feedstock comprises hydrogen, STC, TCS, HCl, and metallurgic silicon. Exemplary feedstock composition, flow-rates, and temperatures are provided. Alternate means of producing the feedstock are described, including a method whereby the feedstock is the product of an upstream STC converter.

### CROSS-REFERENCE TO RELATED APPLICATION

This application claims the benefit under 35 U.S.C. §119(e) of U.S. Provisional Patent Application No. 61/779,613 filed Mar. 13, 2013, which application is incorporated herein by reference in its entirety.

### FIELD OF THE INVENTION

The present invention relates generally to chlorination chemistry, more particularly to exothermic chlorination reactions and management of the heat generated thereby.

### BACKGROUND

Chlorination is an integral part of many chemical operations. As an example, in current practice, crude trichlorosilane (TCS) for conversion to refined TCS and/or silane gas is produced by one of two alternate methods, commonly known as: 1) direct chlorination, and 2) hydrochlorination.

In the direct chlorination process, gaseous hydrogen chloride (HCl) in pure form and solid metallurgic silicon (MGSi) are fed to a reactor in roughly stoichiometric amounts, where the HCl reacts with the MGSi according to the following formula to produce crude TCS and, to a lesser degree, silicon tetrachloride (STC):

3HCl+1MGSi→1SiHCl₃+H2

This reaction typically proceeds under operating conditions of about 3 barg and 300° C. to 330° C. HCl conversion, in the presence of a stoichiometric excess of MGSi, is quantitative at essentially 100% conversion per pass. The reaction is very fast, enabling a reactor hold-up time of about 50 seconds. The reaction is also highly exothermic. The heat of reaction is typically removed from a direct chlorination reactor by means of internal cooling coils and/or reactor cooling jackets disposed on the external shell of the reactor.

Heat removal poses significant equipment design and control issues. Improper design and control can result in hot spots and localized erosion. Hot spots are disadvantageous for a number of reactions. For example, they promote over-chlorination producing unwanted STC. They also cause the formation of undesired sintered metallurgic silicon, and the formation of agglomerations of silicon metal called “clinkers”. Sintered silicon is less reactive than unsintered silicon and reduces reactor productivity. Clinkers accumulate in the reactor and also reduce reactor productivity. Hot spots, when in the proximity of interior reactor metal surfaces, promote erosion of those surfaces. Erosion of the reactor shell can lead to reactor breach and dangerous emissions of reactor content to the ambient environment. Erosion of an internal cooling coil can lead to coil leaks and the introduction of the cooling medium into the reactor, requiring reactor shutdown and maintenance.

The HCl in a direct chlorination feedstock is typically comprised of HCl recovered from the TCS deposition process and off-gas recovery systems commonly found in polysilicon manufacturing plants. When TCS is decomposed to polysilicon in a continuous vapor deposition reactor (CVD reactor) STC is produced as an unwanted byproduct according to the following formula:

4HSiCl₃→1MGSi+3SiCl₄+2H₂.

In the direct chlorination process, STC produced in the CVD reactor is subsequently converted back to TCS and HCl in an STC converter, operating at temperatures ranging from as low as 300° C. to 400° C. to as high as 900° C. to 1300° C., and pressures ranging from 1 barg to 10 barg, according to the following formula:

1SiCl₄+1H₂→1SiHCl₃+HCl.

STC conversion is around 20% per pass. STC converter products are separated from each other in an off-gas recovery system. The recovered HCl is recycled back to the direct chlorination reactor for reconversion to TCS. The recovered STC is recycled back to the STC converter. The recovered H₂ is substantially recycled back to the STC converter. The recovered TCS is recycled back to the CVD reactor.

The direct chlorination process enjoys several advantages compared to the hydrochlorination process discussed below. The direct chlorination process is inherently safer than the hydrochlorination process because it is operated at significantly lower pressure and temperature. Further, because the operating temperature and pressure are relatively low, the reactor shell and internal units can be made from inexpensive and readily available carbon steel—compared with expensive Incoloy 800H required for hydrochlorination. Disadvantages comprise the need to remove the exothermic heat of reaction, high potential for hot spots, erosion, and need for an STC converter. It is also difficult to scale up the reactor to achieve higher production rates and economies of scale.

In the hydrochlorination process, gaseous hydrogen, STC, and solid MGSi are fed into a reactor where the STC and hydrogen react with the MGSi according to the following formula to produce crude TCS:

3SiCl₄+2H₂+1MGSi→4SiHCl₃.

This reaction typically runs around 33 barg and 500° C. to 550° C. The reaction is relatively slow and slightly endothermic. Reactor hold-up time runs around 90 seconds. No reactor heating is typically employed, since the endotherm is offset by pre-heating feedstock to a temperature slightly in excess of the desired reactor operating temperature. For example, if the desired operating temperature is 500° C., the reactor feedstock may be heated to 550° C. The endothermic heat of reaction is thus satisfied by the cooling of the gaseous feedstock material. Gaseous feedstock is comprised of hydrogen and STC, typically in a 1:1 to 2:1 H₂:STC molar ratio. A large excess of STC is fed into the reactor because STC conversion per pass is relatively low, for example 20% conversion per pass. The large excess of STC in association with a large excess of hydrogen gas plus the TCS reaction product serves to agitate and fluidize the hydrochlorination reaction bed comprised of solid metallurgic silicon. The high degree of fluidization results in a relatively homogenous reactor content.

The effluent from the hydrochlorination reactor is separated into constituent parts in an off-gas system. Unreacted STC and hydrogen are recycled back into the hydrochlorination reactor. STC produced in the CVD reactor and separated in the CVD reactor off-gas treatment system is also fed into the hydrochlorination reactor for conversion to TCS. Small amounts of HCl may be produced in the CVD reactor. To the extent formed, this HCl or a portion thereof may be recycled to the hydrochlorination reactor.

Advantages of the hydrochlorination reactor compared to the direct chlorination reactor include the absence of cooling systems, thus enabling easy scale-up to large-sized highly productive reactors, greater economies of scale due to the larger sized reactors, absence of hot spots, reduced maintenance, and elimination of the requirement for an STC converter and its associated off-gas treatment system. Disadvantages include the requirement for much higher operating temperature and pressure with inherently greater safety hazard, longer reactor hold-up time—almost twice that for direct chlorination, large excess of reactants fed to the reactor requiring recovery and recycle efforts, relatively large-sized reactor, significantly more expensive fines recovery system, problematic fines recycle system (the down-comer leading from the cyclone back to the reactor tends to plug), very thick reactor walls required by the high operating temperature and pressure, and expensive materials of construction. The hydrochlorination reactor must be made from expensive and sometimes hard to obtain Incoloy 800H, because this is one of the few materials of construction capable of withstanding the reactors high temperature and pressure operating conditions.

### SUMMARY

Reactor design and operating conditions that enable efficient temperature management in a chlorination reaction, for example a reactor for the direct chlorination of metallurgic silicon by hydrogen chloride, are provided. The chlorination reaction is an exothermic reaction, and according to the present process the heat generated by the reaction is absorbed by a cooling fluid that is in admixture with the reactants and products, thus eliminating the necessity of cooling the reactor via internal or external cooling coils. Reactor temperature may therefore be managed by controlling, for example, the temperature and composition of the reactor feedstock. Exemplary feedstock compositions, temperatures and other input conditions are described below. Various means of producing the feedstock are described, including a method whereby the feedstock is the product of an upstream STC converter. The present disclosure provides a new reactor design and new operating conditions which capture the advantages of both direct chlorination and hydrochlorination, and eliminate the drawbacks of each. In the present disclosure, the terms direct chlorination or direct chlorination reactor may optionally be substituted for a reference to chlorination or chlorination reactor (chlorinator) to make clear that the present disclosure provides an improvement on a direct chlorination reaction wherein gas phase coolant is introduced into the direct chlorination reactor in order to perform a direct chlorination reaction under adiabatic conditions.

In one aspect, the present disclosure provides a process comprising:
a. providing a reactor sited in an environment, the reactor comprising a reactor shell enclosing reactor contents;
b. operating the reactor in a continuous mode at an operating temperature and an operating pressure;
c. introducing a gas phase chloride donor to the reactor under input conditions;
d. introducing a gas phase coolant to the reactor under input conditions comprising a coolant temperature less than the reactor operating temperature;
e. introducing a chloride acceptor to the reactor under input conditions;
f. transferring chloride from the donor to the acceptor within the reactor, the transfer being exothermic and generating heat within the reactor; and
g. recovering a gas phase product exiting the reactor under exit conditions.

In optional embodiments, the process may be further characterized by one or more of the following criteria: the reactor shell comprises carbon steel; the chloride donor is HCl; the coolant comprises STC; the coolant comprises TCS; the coolant comprises DCS; the coolant comprises hydrogen; the coolant comprises STC and hydrogen; chloride donor is in admixture with hydrogen and TCS; the chloride donor is in admixture with STC and TCS; the chloride donor is HCl in admixture with hydrogen; the chloride donor is HCl in admixture with hydrogen and STC; the chloride acceptor is MGSi particles; the chloride donor comprises HCl and the chloride acceptor comprises MGSi; the process is run adiabatically; the process is run near adiabatically; the input conditions for the HCl and the input conditions for the gas phase coolant comprise a temperature selected to maintain the reactor operating temperature within desired range; the the reactor lacks cooling surfaces in contact with the reactor shell or the reactor contents; the reactor lacks an internal cooling coil that provides cooling surfaces in contact with the reactor contents; the reactor lacks an external cooling jacket that provides cooling surfaces in contact with the reactor shell.

For example, the present disclosure provides a process comprising:
a. providing a reactor sited in an environment, the reactor comprising a reactor shell enclosing reactor contents;
b. operating the reactor in a continuous mode at an operating temperature and an operating pressure;
c. introducing gas phase HCl to the reactor under input conditions;
d. introducing gas phase coolant to the reactor under input conditions comprising a coolant temperature less than the operating temperature;
e. introducing MGSi to the reactor under input conditions;
f. transferring chloride from HCl to MGSi within the reactor, the transfer being exothermic and generating heat within the reactor; and
g. recovering a gas phase product comprising TCS exiting the reactor under exit conditions.

Where optionally: the gas phase coolant comprises at least one of hydrogen, STC, TCS and DCS; and/or the gas phase coolant comprises STC and hydrogen; and/or HCl is in combination with the gas phase coolant upon introduction to the reactor; and/or the operating temperature of the reactor is within the range of 250° C. to 450° C.; and/or the operating pressure of the reactor is within the range of 1 barg to 15 barg; and/or the HCl and the coolant enter the reactor at a molar ratio of coolant:HCl of 2:1 to 20:1; and/or the heat is not transmitted to a cooling coil or a cooling jacket; and/or the process is operated under adiabatic conditions. The temperature of the gas phase HCl and the temperature of the gas phase coolant, which may be the same temperature in the event that the HCl and coolant are in admixture prior to entering the reactor, may be selected so as to achieve a desired operating temperature for the reactor, where the operating temperature may be a constant temperature, e.g., varying no more than about ±5%, of about, for example, 320° C. For example, the process may be performed such that the chloride donor and the coolant are in admixture upon being introduced into the reactor, the admixture having a temperature within the range of 120-280° C. and being at least 30° C. less than the operating temperature of the reactor, the operating temperature of the reaction being a temperature within the range of 250-400° C. and the operating pressure being 1-15 barg, the admixture having a molar ratio of coolant:HCl of 2:1 to 20:1. Any of these values may be replaced with other values as set forth herein for the specified parameter. The composition and temperature of the admixture may be selected so as to maintain the operating conditions within the reactor at a steady state.

The process as disclosed herein may further comprise:
h. providing an STC converter;
i. delivering STC and hydrogen to the STC converter;
j. recovering an off gas comprising HCl and TCS from the STC converter;
k. optionally adjusting the temperature of the off-gas; and
l. providing the off gas in unrefined form to the reactor to thereby provide at least a portion of the chloride donor and the coolant.
   Optionally, the off gas may further comprise STC; and/or HCl may be added to the off gas prior to the off gas being provided in unrefined form to the reactor.

In addition, the process as disclosed herein may further comprise:
m. introducing the product gas of step g) to an off gas recovery system whereby TCS is separated from hydrogen;
n. introducing at least a portion of the hydrogen from step l) to a hydrogen compressor to provide compressed hydrogen;
o. introducing at least a portion of the compressed hydrogen from step m) to the STC converter.

In another aspect, the present disclosure provides a system comprising:
a. an STC converter into which STC and hydrogen are introduced and a first product gas comprising TCS and HCl is recovered; and
b. a chlorination reactor in fluid communication with the STC converter, where the first product gas and MGSi are introduced into the chlorination reactor and a second product gas comprising hydrogen and TCS is recovered from the chlorination reactor;
where the STC converter delivers unrefined first product gas to the chlorination reactor.

Optionally, the system may be characterized by one or more of the following criteria: the 1st stage reactor is an isothermal reactor; the 1^{st} stage reactor is an adiabatic reactor; the system further comprises a cooling unit to cool the first product gas to a desired input temperature to the chlorination reactor; the system further comprises an HCl source, where the HCl source is in fluid communication with a conduit in fluid communication with both the 1st stage reactor and the 2nd stage reactor; the system further comprises an off gas recovery system in fluid communication with the 2nd stage reactor, where the off gas recovery system may separate TCS from hydrogen; the off gas recovery system is in fluid communication with a hydrogen compressor, where the hydrogen compressor may compress the hydrogen separated by the off gas recovery system; the system further comprises a reactor where polysilicon may be prepared from TCS. The system may optionally include a temperature control means, e.g., a cooling jacket or a heating coil surrounding the conduit, to control the temperature of the first product gas before it enters the 2nd stage reactor. The system may optionally include a temperature monitoring means, e.g., a thermocouple, to monitor the temperature within the 2nd stage reactor.

In another aspect, the present disclosure provides a system comprising a chlorination reactor in fluid communication with a source of MGSi and also in fluid communication with a source of hydrogen chloride, the chlorination reactor also in fluid communication with at least one of a source of hydrogen and a source of STC. The hydrogen and/or STC provide the coolant of the present disclosure which allows the chlorination reaction taking place within the chlorinator to be performed in an adiabatic manner. In various optional embodiments, where any two or more of the following embodiments may be combined to describe an embodiment of the invention (so long as the embodiments are not mutually exclusive): the chlorination reactor is also in fluid communication with an STC converter, and the STC converter provides the source of STC (an STC converter is typically far from 100% efficient in converting STC to TCS, and accordingly the effluent from an STC converter will typically contain STC); the chlorination reactor is not in direct fluid communication with an STC converter, i.e., the effluent from an STC converter is not directly fed into the chlorination reactor, however, an STC converter may be present elsewhere in the system, e.g., an STC converter may be used to treat the STC that is present in the off gas from a CVD reactor that produces polysilicon by the Siemens process, in which case the product from this STC converter is not directly fed into the chlorinator but instead is fed into an off gas recovery system which generates a fraction enriched in STC which may be used as the source of STC in the chlorination reaction; the chlorination reactor is in fluid communication with a fractionation column, and an effluent from the fractionation column provides the source of STC, where this may occur, as mentioned previously, when the CVD reactor is in fluid communication with an STC converter, and the STC converter is in fluid communication with an off gas recovery system that includes a fractionation column; the system further comprises an off gas recovery system in fluid communication with the chlorination reactor, the off gas recovery system providing separation of components of off gas from the chlorination reactor, the off gas recovery system providing an off gas fraction enriched in hydrogen where at least some of the off gas fraction enriched in hydrogen provides the source of hydrogen to the chlorination reactor, in other words, the hydrogen present in the off gas from the chlorination reactor is recycled back into the chlorination reactor after having pass through an off gas recovery system that provides a fraction enriched in hydrogen; the chlorination reactor is a direct chlorination reactor which reacts hydrogen chloride with MGSi in a fluidized bed to produce TCS; the chlorination reactor in not in direct fluid communication with a STC converter such that the effluent from an STC converter is not directly introduced into the chlorination reactor; the system further comprises a source of STC in fluid communication with the chlorination reactor, whereby STC is introduced into the chlorination reactor along with hydrogen chloride and MGSi; the system further comprises a source of hydrogen in fluid communication with the chlorination reactor, whereby hydrogen is introduced into the chlorination reactor along with hydrogen chloride and MGSi; the system further comprises a chemical vapor deposition (CVD) reactor for producing polysilicon and a CVD off gas.

In another aspect, the present disclosure provides a process comprising a) performing a chlorination reaction in a chlorination reactor at a first temperature, where MGSi and hydrogen chloride are reacted together to provide a product gas comprising trichlorosilane; b) introducing a coolant selected from hydrogen and STC to the chlorination reactor, the coolant being introduced at a second temperature, the second temperature being less than the first temperature, the second temperature selected so that the chlorination reactor is performed under adiabatic conditions. In various optional embodiments, where any two or more of the following embodiments may be combined to describe an embodiment of the invention (so long as the embodiments are not mutually exclusive): the chlorination reactor is in fluid communication with an STC converter, and the STC converter provides the source of STC; the chlorination reactor is not in direct fluid communication with an STC converter; the chlorination reactor is in fluid communication with an off gas recovery system, where the off gas recovery system generates a fraction enriched in STC, and the fraction enriched in STC is introduced into the chlorination reactor to provide the source of STC to the chlorination reactor; an effluent from an STC converter is not directly introduced into the chlorination reactor; STC is introduced into the chlorination reactor along with hydrogen chloride and MGSi; the chlorination reactor is in fluid communication with an off gas recovery system, where the off gas recovery system generates a fraction enriched in hydrogen, and the fraction enriched in hydrogen is introduced into the chlorination reactor to provide the source of hydrogen to the chlorination reactor; the process further comprises performing the Siemens process for polysilcion production.

In standard direct chlorination reactors, heat of reaction (released when HCl chlorinates metallurgic silicon) must be removed by heat transfer to a contained cooling fluid, where the cooling fluid is contained in internal cooling coils and/or conduits applied to the shell of the reactor forming a co-called cooling jacket. This system of heat transfer will be referred to herein as external cooling. External cooling makes scale-up difficult: the practical limit is a reactor size of one meter in diameter. The present disclosure provides chemical processes having improved temperature management, so that little to no external cooling is required. Accordingly, a chlorination reaction may be conducted in larger reactors, for example, reactors of, in various embodiments, 2, 2.5, 3 or more meters in diameter. Larger size reactors enable higher production rates from a single reactor with concomitant economy of scale.

The present disclosure provides a reactor design and operation in which little to no external cooling is required because the reactor is operated in a way that the feed to the reactor will absorb the heat of reaction yielding an adiabatic or near-adiabatic operating conditions at a temperature of about, for example, 300° C. to 350° C. This is possible because the molar feed rate exiting the reactor will be an order of magnitude greater than the molar feed rate exiting the standard direct chlorination reactor. Further advantageously, the reactor gaseous effluent may be comprised of STC, TCS, and hydrogen, which all have inherently high heat capacities. Thus, by appropriately choosing the proper feed temperature of the combined admixture, the energy released in the reaction may be exactly balanced by the energy required to heat the combined admixture to the desired reactor operating temperature.

The details of one or more embodiments are set forth in the description below. The features illustrated or described in connection with one exemplary embodiment may be combined with the features of other embodiments. Other features, objects and advantages will be apparent from the description, the drawings, and the claims. In addition, the disclosures of all patents and patent applications referenced herein are incorporated by reference in their entirety.

### BRIEF DESCRIPTION OF THE DRAWINGS

Features of the invention, its nature and various advantages, will be apparent from the accompanying drawings and the following detailed description of various embodiments.

FIG. 1 provides a schematic view of a chlorination reactor (also referred to herein as a chlorinator) according to the present disclosure. The chlorination reactor of FIG. 1 may be referred to as a 2^{nd} stage reactor when it operates in combination with an STC converter, where the STC converter may be referred to as a 1^{st} stage reactor.

FIG. 2A provides a schematic view of a 2^{nd} stage reactor in combination with a 1st stage reactor, where the 1^{st} stage reactor generates a feedstock for the 2^{nd} stage reactor, and where the 1^{st} stage reactor may be an STC converter.

FIG. 2B provides a schematic view of how the combination of the 1st stage and 2^{nd} stage reactors illustrated in FIG. 2A may be integrated into a plant design for producing polysilicon. FIG. 2A is an expanded view of the region of FIG. 2B enclosed by a dashed line.

FIGS. 3A and 3B provide a schematic view of how a chlorination reactor may be modified to enable adiabatic operation when the plant incorporates a standard CVD off-gas system comprising STC conversion to TCS and HCl, standard separation of STC converter products into TCS, STC, HCl, and hydrogen, and standard recycle of HCl to the chlorination reactor. FIG. 3A is an expanded view of the region of FIG. 3B enclosed by a dashed line.

### DETAILED DESCRIPTION OF THE INVENTION

In one aspect, the present disclosure provides a chlorination process. In the chlorination process, a chloride donor and a chloride acceptor are combined in a reactor and chloride is transferred from the donor to the acceptor with the release of heat. If the donor is HCl, the chlorination process is an exothermic reaction. Optionally, at least one of the chloride donor and chloride acceptor is a silicon containing compound. As examples, the chloride acceptor may be a silicon-containing compound selected from any one or more of metallurgic silicon (MGSi), silane, disilane, monochlorosilane, dichlorosilane and trichlorosilane. MGSi may be the chloride acceptor. MGSi is a commercially available material, available from many suppliers. It can be produced by a submerged-electrode arc furnace, using quartzite gravel as the starting material. The chloride donor may be HCl. HCl is a commercially available material, available from many suppliers. It can be produced by the Siemen's process for polysilicon manufacture.

An adiabatic process refers to any process occurring without gain or loss of heat within a system (i.e. during the process the system is thermodynamically isolated—there is no heat transfer with the surroundings). This is the opposite of a diabatic process, where there is heat transfer. An adiabatic process can occur if the container of the system has thermally-insulated walls or the process happens in an extremely short time, so that there is no opportunity for significant heat exchange. In other words, a transformation of a thermodynamic system can be considered adiabatic when it is quick enough or so well insulated such that no significant heat is transferred between the system and the outside (e.g., to cooling coils containing a heat transfer medium). An exothermic adiabatic reaction is one where the temperature of the reaction products are greater than that of the reaction feed admixture. As used herein, the term internal coolant refers to coolant that is in admixture with the reactants and products of the chlorination reaction. Internal coolant may also be referred to as inherent coolant. Internal coolant allows for internal cooling of the reactor contents. The term external coolant refers to coolant that is not in admixture with the reactants and products of the chlorination reaction. The use of external coolant will be referred to herein as external cooling. An external coolant may, for example, be contained within the walls of a conduit that traverses the interior of the reactor. A cooling coil is an example of such a conduit, and the coolant within a cooling coil is an example of an external coolant. A cooling coil allows for external cooling of the reactor contents. Another example of external cooling is a cooling jacket which is fitted to the outside of the reactor shell. Each of a cooling coil and a cooling jacket is exemplary of active external cooling, whereby heat is transmitted to coolant conduit and then to coolant, where the coolant is actively circulated or otherwise caused to travel through the conduit. External cooling may also occur passively, which occurs when the reactor shell is incompletely insulated and some heat leaks away from the reactor directly into the environment.

In one aspect, the process of the present disclosure includes providing a reactor sited in an environment, where the reactor comprises a reactor shell that encloses the reactor contents. The reactor shell is the barrier between the inside and the outside of the reactor. The reactor shell envelops an internal controlled environment in which a chlorination reaction as discussed below, takes place. Accordingly, the reactor may be referred to herein as a chlorinator. The reactor may, but may not, have internal heating or cooling coils. In addition, or alternatively, the reactor may, but may not, have an external heating or cooling jacket. Internal coils, an external jacket, and indeed any means by which conduit for cool fluid is made to contact the hot reactor shell or hot reactor contents so that the cooling fluid absorbs and thereafter transports away and dissipates heat from the reactor, is optionally absent from the chlorinator of the present disclosure. In one embodiment, the reactor does not have any specialized heat removal equipment so that all of the excess heat, i.e., all of the heat that is not simply dissipated to the environment, is captured in heating a cooling fluid that is in admixture with the reactants and products of the chlorination reactor. The environment containing the reactor, i.e., within which the reactor is sited, may be ambient conditions of temperature and pressure, e.g., a temperature of about 20-30° C. and a pressure of atmospheric pressure.

The reactor may be thermally insulated so that heat from the reactor does not passively escape into the environment. An insulated reactor is advantageous for several reasons. For example, from the viewpoint of safety, an insulated reactor avoids the presence of a hot external reactor shell surface which may burn people in the vicinity of the reactor. In addition, when the reactor is sited outdoors in the absence of a covering roof and/or enclosing walls, rain and/or wind which contacts the reactor will not be able to impact the temperature of the reactor when that reactor is thermally insulated. A perfectly thermally insulated reactor allows for the process of the present disclosure to operate under adiabatic conditions. Perfect insulation is difficult and expensive to achieve, so the process of the present disclosure may proceed under near adiabatic conditions, whereby a small amount of heat passively escapes from the reactor into the environment. Under near adiabatic conditions, the outside of the reactor may be slightly above ambient temperature, for example, within +2° C., or +4° C., or +6° C. or +8° C. or +10° C. compared to ambient temperature.

In order to operate a reactor at the high pressure and high temperature typically associated with hydrochlorination reactors, and yet avoid or minimize corrosion due to HCl, Incoloy 800H has proven to be the construction material of choice. Development of increasingly larger hydrochlorination reactors has been limited by the mechanical and strength properties of Incoloy 800H. Current metallurgy and metal plate production technology has limited plate thickness to 80 mm. Addition of other alloying materials to increase high temperature tensile strength appears to also reduce ductility (i.e., increase embrittlement). The reactor and system of the present disclosure can utilize Incoloy 800H, but as will be described herein, the reactor and system of the present disclosure operates at lower temperatures than typically utilized for hydrochlorination reactions, and accordingly carbon steel and other materials may be used to form the reactor shell.

In addition to a reactor shell, the reactor may include a distributor tray. Levenspiel's “Fluidization Engineering” discloses several suitable distributor trays. The distributor tray may be located near the bottom of the chlorination reactor. In effect, the distributor tray provides for a “false bottom” beneath which is a plenum into which the reactor feed is directed. In general, the purpose of a distributor tray in a fluid bed reactor (FBR), also sometimes referred to as a gas distributor plate, is to spread out the inlet gases so as to have an even or uniform bubbling action across the bed diameter, but with a minimum of solids abrasive wear and a minimum of distributor plate pressure drop. An uneven spread of inlet gases causes excessive central bubble formation which leads to bypassing, and also allows “dead spots” to form where there is an insufficient amount of reaction gas available. As mentioned herein, the chloride acceptor may be MGSi. However, it is recognized that MGSi is abrasive in nature and the undue localized jetting of reaction gas may cause wear spots on the reactor's wall and some portions of the distributor plate. Also, a higher than necessary pressure drop increases compressor horsepower, and therefore wastes utilities. The use of a gas distributor plate addresses the problems associated with use of MGSi as the chloride acceptor.

Due to the high exotherm of chlorination reactions (on the order of 50-60 kcal/g-mole) a high degree of fluidization is necessary to maintain the MGSi particle surface at a low enough temperature such that particle-to-particle agglomeration does not occur. It is also necessary to have the inlet gas temperature rapidly move past the minimum 250-280° C. range, where the surface reaction can be extinguished, but yet keep the Stage 2 bulk gas off-gas temperature sufficiently low (e.g., under about 400° C.) so that TCS formation is favored over STC formation. The distributor tray helps achieve these advantageous effects, although the reactor may be operated without a distributor tray.

The reactor may optionally have an expanded head or a cyclone to handle the fines generated during the chlorination reaction. During the course of the reaction, some fine material comprising metallurgic silicon, and catalyst if present, may be blown out of the fluidized bed. These fines may be captured in a calming zone at the top of the reactor, which is integral to and formed by an expanded reactor head. The fines that have been captured in this calming zone fall back into the fluidized bed portion of the reactor where they participate in the chlorination reaction. Alternatively, the fines may be captured in a cyclone located inside the reactor at the top of the reactor, or located external to the reactor on the product transfer line leaving the reactor. Fine captured by the cyclone are directed back into the reactor through a down-comer for further reaction. In one embodiment, the reactor used in the process of the present disclosure contains a calming zone. In an alternative embodiment the reactor used in the process of the present disclosure includes or is in combination with a cyclone.

Compared to a reactor employed in a standard direct chlorination reaction, the reactor utilized in the presently disclosed process has multiple advantages. For example, since little to no heat removal from the reactor is required, the reactor may employ a simplified design having little to no heat handling equipment, thus reducing installed equipment cost and maintenance costs, and affording a longer operating life for the reactor. In addition, the reactor can be scaled up very easily to large size because heat removal is no longer the limiting design factor. In embodiments, the reactor is generally cylindrical having a diameter of greater than 1.0, or 1.5, or 2, or 2.5, or 3 meters. As a result, for example, it is possible to build a single reactor capable of producing enough crude TCS to produce 10,000 MTA polysilicon—compared to standard direct chlorination reactors which are constrained by heat removal problems to only ⅓^{rd} or less of this capacity.

Compared to a reactor employed in a standard hydrochlorination reaction, the reactor utilized in the presently disclosed process also has multiple advantages. For example, the lower operating pressure and temperature of about 3 barg and about 300° C., compared to about 33 barg and 550° C. in a standard hydrochlorination reactor, translate into improved inherent safety and lower capital and operating costs. The relatively mild operating conditions available in the chlorination process of the present disclosure enable the use of low cost carbon steel for reactor shell construction in lieu of high cost INCOLOY™ alloys such as INCOLOY 800H™, thereby reducing capital expense for building the reactor by a factor about 10 times. Indeed, the process and systems described herein can utilize a chlorination reactor formed from carbon steel, e.g., 321 SS and 347 SS are acceptable materials from which to form the reactor. The problem of fines can be managed by using calming zones for metallurgic silicon recovery instead of more expensive and operationally problematic cyclones. Finally, compared to standard hydrochlorination reactors, the reactors of the present process may be smaller size and more productive.

In one aspect, the process of the present disclosure includes operating the chlorinator within a specified temperature range and/or a within a specified pressure range. In embodiments, the temperature within the reactor is maintained within the range of 250-450° C., 250-400° C., 250-350° C., 300-450° C., 350-450° C., 300-400° C., 300-350° C., or 350-400° C. The upper temperature is lower than the 500° C. typically used by reactors operating a standard hydrochlorination process. In embodiments, the pressure within the reactor is maintained within the range of 1-15 barg, 1-10 barg, 1-8 barg, 1-6 barg, 2-10 barg, 2-8 barg, or 2-6 barg. Each of the aforesaid temperature ranges may be combined with any of the aforesaid pressure ranges. For example, the reactor may be operated at 250-350° C. and 1-10 barg or 300-350° C. and 1-6 barg.

The operating temperature and pressure within the reactor will depend, to some extent, on how quickly the gaseous feedstock(s) are allowed to enter the reactor, and how quickly the gaseous products exit the reactor. In other words, the flow rate and hold up time may influence the operating pressure and temperature. The hold up time will depend, in part, on the size and configuration of the reactor. A longer thicker reactor will have a longer hold up time than a shorter thinner reactor. The chlorination reaction that takes place between the chloride donor and the chloride acceptor is a fast reaction at temperatures above about 250° C., allowing for a short hold up time, that is, a hold up time in the range of 10 to 100 seconds, or 10 to 90 seconds, or 10 to 80 seconds, or 20 to 100 seconds, or 20 to 90 seconds, or 20 to 80 seconds, or 20 to 70 seconds, or 30 to 100 seconds, or 30 to 90 seconds, or 30 to 80 seconds, or 30 to 70 seconds, or 30 to 60 seconds. In other embodiments, the hold up time is less than 100 seconds, or less than 90 seconds, or less than 80 seconds, or less than 70 seconds, or less than 60 seconds.

The temperature of the gas phase HCl and the temperature of the gas phase coolant, which may be the same temperature in the event that the HCl and coolant are in admixture prior to entering the reactor, may be selected so as to achieve a desired operating temperature for the reactor. Optionally, the operating temperature may be a constant temperature, i.e., varying no more than about ±5%. The operating temperature of the reactor may be, for example, about 300-350° C., or about 320° C.

In one aspect, the process of the present disclosure includes introducing a gas phase component to the reactor under input condition, where the component is primarily intended to function as a coolant. For convenience, the component will be referred to herein as the coolant where the coolant may be one chemical or a mixture of chemicals. Unlike traditional cooling fluids, the coolant as used herein is in admixture with the chloride donor and chloride acceptor. This is in contrast to the use of traditional cooling fluids, which never come into direct contact with the reactor contents, but instead travel through and remain within conduits. The conduits are formed of heat transmitting materials that make direct contact with either the reactor content itself, or with the reactor shell which is, in turn, in direct contact with the reactor contents, so that heat from the reactor is indirectly transmitted to the cooling fluid. The present process provides for direct transfer of heat from the reactor contents to the cooling fluid, i.e., heat of reaction does not travel through material which forms a conduit for the cooling fluid.

According to the present process, because the cooling fluid is in direct contact with the reactants and products of the reaction, the cooling fluid should advantageously not interfere with or preclude the chemistry of the desired chlorination reaction.

The amount of cooling fluid introduced into the reactor is preferably selected so as to be able to absorb all, or nearly all, of the heat generated by the chlorination reaction. In other words, in order to maintain a selected reactor operating temperature while introducing chloride donor and/or chloride acceptor into a reactor, the heat generated by the exothermic chlorination reaction should be approximately equal to the heat needed to raise the temperature of the cooling fluid to the operating temperature of the reactor. If too little cooling fluid is introduced, the reactor operating temperature will rise above a desired maximum, while if too much cooling fluid is introduced, the reactor operating temperature will fall below a desired minimum temperature. If the reactor operating temperature rises above a desired maximum, there can be serious undesirable consequence. For example, the material that forms the reactor shell is exposed to higher than anticipated temperatures, which may weaken the shell to the point of vessel failure. As another example, the chlorination reaction may produce undesired by-products, such as fused particles of MGSi, the presence of which may slow down the desired chlorination reaction and/or necessitate periodic removal of the fused particles which reduces the operating efficiency of the reactor, or excessive formation of STC thereby reducing yield to desired TCS product. If the reactor operating temperature falls below a desired minimum, there can likewise be serious undesirable consequences. The chlorination reaction, while being an exothermic reaction, nevertheless needs a certain amount of heat in order to proceed. If the temperature within the reactor is too low, the chlorination reaction will either not begin, or will proceed only partially. Accordingly, it is desirable to introduce cooling fluid into the reactor in the proper amount and temperature.

The input conditions of the cooling fluid will impact the effectiveness of the fluid to achieve the desired cooling of the reactor contents. For example, as the amount of cooling fluid is increased, all other factors being kept constant, then the reactor contents are liable to cool below the desired minimum. Conversely, if the amount of cooling fluid is decreased, all other factors being kept constant, then the reactor contents are liable to heat above the desired maximum. As the temperature of the cooling fluid is decreased, all other factors being kept constant, then the reactor contents are liable to cool below the desired minimum. However, if the temperature of the cooling fluid is increased, all other factors begin kept constant, the reactor contents are liable to heat above the desired maximum. In selecting the input conditions for the cooling fluid, it is preferred that those conditions provide for a gaseous cooling fluid. In other words, the temperature of the cooling fluid is preferably above the dew point of the fluid.

However, the temperature of the cooling fluid, while it is preferably above the dew point of the fluid, is also preferably below the operating temperature of the chlorinator. In various embodiments, the cooling fluid has a temperature which is less than but within 20° C., 40° C., 50° C., 55° C., 60° C., 65° C., 70° C., 75° C., 80° C., 85° C., 90° C., 95° C., 100° C., 150° C., or 200° C. of the operating temperature of the chlorinator. In other embodiments, the temperature of the cooling fluid is at least 20° C., 40° C., 50° C., 55° C., 60° C., 65° C., 70° C., 75° C., 80° C., 85° C., 90° C., 95° C., 100° C., 150° C., or 200° C. below the operating temperature of the chlorinator.

In addition to the amount and temperature of the cooling fluid, it is important to keep in mind the identity of the fluid and relative components thereof. Some cooling fluid components require more heat to increase their temperature from T₁ to T₂ than do other cooling fluid components. This ability of a material to absorb heat may be measured by molar heat capacity. The molar heat capacity of gas phase STC is about 90 J/(mol K) while the molar heat capacity of gas phase hydrogen is about 29 J/(mol K). Accordingly, a mole of STC absorbs more heat as it warms from T₁ to T₂, than does a mole of hydrogen. As the cooling fluid is enriched in STC at the expense of hydrogen, all other factors being equal, the cooling fluid has a greater capacity to absorb heat and so the reactor contents are liable to cool below the desired minimum. Conversely, as the cooling fluid is enriched in hydrogen at the expense of STC, the cooling fluid cannot absorb as much heat, and is less effective. This effect can be counter-acted by using more of a cooling fluid having a lower molar heat capacity. However, using more cooling fluid requires a larger reactor to contain the larger amount of cooling fluid, which adds to the capital cost of the system. Another disadvantage of using more cooling fluid is that the reactants and products become diluted, which reduces the operating efficiency of the system.

In one aspect, the feed to the chlorinator may be the off gas recovered from an STC converter. In an STC converter, STC and hydrogen are introduced and a mixture of TCS, STC, hydrogen and HCl are produced as an off gas. This off gas includes a chloride donor (HCl) in admixture with cooling gas (TCS, STC and hydrogen). An STC converter may be operated so as to achieve various relative amounts of HCl and cooling gas in the off gas, e.g., by varying the ratio of hydrogen and STC in the feed. Table 1 illustrates four (cases 1-4) exemplary STC converter off gas compositions that may be used as the feedstock for a chlorination reaction.

An illustration of the impacts of changing the molar ratio of cooling fluid to HCl entering the chlorination reactor is shown in the four cases provided in Table 1. More specifically, in each of the 4 cases of Table 1, the amount of HCl entering the reactor is constant at 30 kg-mol/hr, TCS is constant at 30 kg-mol/hr, and STC is constant at 70 kg-mol/hr, however a decreasing amount of hydrogen coolant is present in the feed in going from case 1 to case 4. In case 1, the feed has 370 kg-mol/hr of hydrogen, 30 kg-mol/hr of TCS and 70 kg-mol/hr STC in addition to 30 kg-mol/hr HCl. In cases 2-4, the amount of hydrogen present in the feed is reduced, so that proportionally, the feed has increasing amount of TCS and STC. As a consequence, in case 1, the cooling fluid:HCl molar ratio is 15.7, which decreases to 9.0, then to 5.7, and finally to 4.0 in case 4. As a consequence of decreasing the hydrogen content of the cooling fluid, while keeping the amounts of TCS and STC constant, the reactor temperature must be reduced from 220.5° C. in case 1 to 182.9° C. in case 2, to 150.7° C. in case 3, to 127.8° C. in case 4. The reactor feed temperature is that temperature at which the reactor can be run adiabatically at a given temperature; e.g., 320° C., at a given pressure; e.g., 3 bar(g).

Table 1 shows feedstocks to a chlorination reactor exemplary of STC converter off-gas products where the temperature of the admixture forming the coolant is adjusted to achieve constant operating reaction temperature of 320 degrees centigrade for a constant amount of HCl reaction. The molar ratio of coolant to HCl is 15.7 in case 1. In general, the molar ratio of coolant to HCl may range from about 3:1 to 20:1, or from 4:1 to 19:1, or from 5:1 to 18:1; or from 6:1 to 17:1, or from 7:1 to 16:1, of from 8:1 to 15:1. At the lower end, i.e., 3:1 molar ratio, the required feed temperature approaches the dew point. At the higher end, the size of the direct chlorination reactor for a given hold up time becomes excessive.

TABLE 1

| | Reactor | Reactor | Reactor |
|---|---|---|---|
| | Feed | Feed | Product |
| | Dew Point | Temperature | Temperature |
| | (° C.) | (° C.) | (° C.) |
| | CASE 1 | | |
| VapFrac | 1.00 | 1.00 | 0.9999 |
| T [C.] | 44.9 | 220.5 | 320.0 |
| P [bar(g)] | 3.00 | 3.00 | 3.00 |
| Mole Flow [kgmole/h] | 500.00 | 500.00 | 490.30 |
| MoleFlows [kgmole/h] | | | |
| MoleFlows. HYDROGEN | 370.00 | 370.00 | 380.50 |
| MoleFlows. HYDROGEN | 30.00 | 30.00 | 0.00 |
| CHLORIDE | | | |
| MoleFlows. | 0 | 0 | 0 |
| DICHLOROSILANE | | | |
| MoleFlows. | 30.00 | 30.00 | 39.00 |
| TRICHLOROSILANE | | | |
| MoleFlows. SILICON | 70.00 | 70.00 | 70.75 |
| TETRACHLORIDE | | | |
| MoleFlows. Gsilicon | 0 | 0 | 0.05 |
| Molar Ratio (Diluent:HCl) | — | 15.7 | — |
| | CASE 2 | | |
| VapFrac | 1.00 | 1.00 | 0.99982 |
| T [C.] | 60.5 | 182.9 | 320.0 |
| P [bar(g)] | 3.00 | 3.00 | 3.00 |
| Mole Flow [kgmole/h] | 300.00 | 300.00 | 290.30 |
| MoleFlows [kgmole/h] | | | |
| MoleFlows. HYDROGEN | 170.00 | 170.00 | 180.50 |
| MoleFlows. HYDROGEN | 30.00 | 30.00 | 0.00 |
| CHLORIDE | | | |
| MoleFlows. | 0 | 0 | 0 |
| DICHLOROSILANE | | | |
| MoleFlows. | 30.00 | 30.00 | 39.00 |
| TRICHLOROSILANE | | | |
| MoleFlows. SILICON | 70.00 | 70.00 | 70.75 |
| TETRACHLORIDE | | | |
| MoleFlows. Gsilicon | 0 | 0 | 0.05 |
| Molar Ratio (Diluent:HCl) | — | 9.0 | — |
| | CASE 3 | | |
| VapFrac | 1.00 | 1.00 | 0.99973 |
| T [C.] | 74.1 | 150.7 | 320.0 |
| P [bar(g)] | 3.00 | 3.00 | 3.00 |
| Mole Flow [kgmole/h] | 200.00 | 200.00 | 190.30 |
| MoleFlows [kgmole/h] | | | |
| MoleFlows. HYDROGEN | 70.00 | 70.00 | 80.50 |
| MoleFlows. HYDROGEN | 30.00 | 30.00 | 0.00 |
| CHLORIDE | | | |
| MoleFlows. | 0 | 0 | 0 |
| DICHLOROSILANE | | | |
| MoleFlows. | 30.00 | 30.00 | 39.00 |
| TRICHLOROSILANE | | | |
| MoleFlows. SILICON | 70.00 | 70.00 | 70.75 |
| TETRACHLORIDE | | | |
| MoleFlows. Gsilicon | 0 | 0 | 0.05 |
| Molar Ratio (Diluent:HCl) | — | 5.7 | — |
| | CASE 4 | | |
| VapFrac | 1.00 | 1.00 | 0.99963 |
| T [C.] | 84.7 | 127.8 | 320.0 |
| P [bar(g)] | 3.00 | 3.00 | 3.00 |
| Mole Flow [kgmole/h] | 150.00 | 150.00 | 140.30 |
| MoleFlows [kgmole/h] | | | |
| MoleFlows. HYDROGEN | 20.00 | 20.00 | 30.50 |
| MoleFlows. HYDROGEN | 30.00 | 30.00 | 0.00 |
| CHLORIDE | | | |
| MoleFlows. | 0 | 0 | 0 |
| DICHLOROSILANE | | | |
| MoleFlows. | 30.00 | 30.00 | 39.00 |
| TRICHLOROSILANE | | | |
| MoleFlows. SILICON | 70.00 | 70.00 | 70.75 |
| TETRACHLORIDE | | | |
| MoleFlows. Gsilicon | 0 | 0 | 0.05 |
| Molar Ratio (Diluent:HCl) | — | 4.0 | — |

Table 2 illustrates six cases (cases 5 to 10) which show the effect of using pure hydrogen coolant. Exemplary molar ratios range from 8:1 to 20:1. Below about 8:1, the required feed temperature becomes too low and will quench the chlorination reaction.

TABLE 2

| | Reactor | Reactor | Reactor |
|---|---|---|---|
| | Feed | Feed | Product |
| | Dew Point | Temperature | Temperature |
| | (° C.) | (° C.) | (° C.) |
| | CASE 5 | | |
| VapFrac | 1.00 | 1.00 | 0.9999 |
| T [C.] | −106.9 | 173.0 | 320.0 |
| P [bar(g)] | 3.00 | 3.00 | 3.00 |
| Mole Flow [kgmole/h] | 500.00 | 500.00 | 490.30 |
| MoleFlows [kgmole/h] | | | |
| MoleFlows. HYDROGEN | 470.00 | 470.00 | 480.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 0 | 0 | 0.75 |
| TETRACHLORIDE | | | |
| MoleFlows. Gsilicon | 0 | 0 | 0.75 |
| Molar Ratio (Diluent:HCl) | — | 15.7 | — |
| | CASE 6 | | |
| VapFrac | 1.00 | 1.00 | 0.99987 |
| T [C.] | −103.9 | 136.2 | 320.0 |
| P [bar(g)] | 3.00 | 3.00 | 3.00 |
| Mole Flow [kgmole/h] | 400.00 | 400.00 | 390.30 |
| MoleFlows [kgmole/h] | | | |
| MoleFlows. HYDROGEN | 370.00 | 370.00 | 380.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 0 | 0 | 0.75 |
| TETRACHLORIDE | | | |
| MoleFlows. Gsilicon | 0 | 0 | 0.75 |
| Molar Ratio (Diluent:HCl) | — | 12.3 | — |
| | CASE 7 | | |
| VapFrac | 1.00 | 1.00 | 0.99983 |
| T [C.] | −99.8 | 74.7 | 320.0 |
| P [bar(g)] | 3.00 | 3.00 | 3.00 |
| Mole Flow [kgmole/h] | 300.00 | 300.00 | 290.30 |
| MoleFlows [kgmole/h] | | | |
| MoleFlows. HYDROGEN | 270.00 | 270.00 | 280.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 0 | 0 | 0.75 |
| TETRACHLORIDE | | | |
| MoleFlows. Gsilicon | 0 | 0 | 0.75 |
| Molar Ratio (Diluent:HCl) | — | 9.0 | — |
| | CASE 8 | | |
| VapFrac | 1.00 | 1.00 | 0.99974 |
| T [C.] | −93.6 | −50.2 | 320.0 |
| P [bar(g)] | 3.00 | 3.00 | 3.00 |
| Mole Flow [kgmole/h] | 200.00 | 200.00 | 190.30 |
| MoleFlows [kgmole/h] | | | |
| MoleFlows. HYDROGEN | 170.00 | 170.00 | 180.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 0 | 0 | 0.75 |
| TETRACHLORIDE | | | |
| MoleFlows. Gsilicon | 0 | 0 | 0.75 |
| Molar Ratio (Diluent:HCl) | — | 5.7 | — |
| | CASE 9 | | |
| VapFrac | 1.00 | 1.00 | 0.999 |
| T [C.] | −72.0 | 50.0 | 1083.3 |
| P [bar(g)] | 3.00 | 3.00 | 3.00 |
| Mole Flow [kgmole/h] | 60.00 | 60.00 | 50.30 |
| MoleFlows [kgmole/h] | | | |
| MoleFlows. HYDROGEN | 30.00 | 30.00 | 40.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 0 | 0 | 0.75 |
| TETRACHLORIDE | | | |
| MoleFlows. Gsilicon | 0 | 0 | 0.05 |
| Molar Ratio (Diluent:HCl) | — | 1.0 | — |
| | CASE 10 | | |
| VapFrac | 1.00 | 0.60263 | 0.81382 |
| T [C.] | −72.0 | −91.3 | 320.0 |
| P [bar(g)] | 3.00 | 3.00 | 3.00 |
| Mole Flow [kgmole/h] | 60.00 | 60.00 | 41.87 |
| MoleFlows [kgmole/h] | | | |
| MoleFlows. HYDROGEN | 30.00 | 30.00 | 32.07 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 1.89 |
| TRICHLOROSILANE | | | |
| MoleFlows. SILICON | 0 | 0 | 0.16 |
| TETRACHLORIDE | | | |
| MoleFlows. Gsilicon | 0 | 0 | 7.76 |
| Molar Ratio (Diluent:HCl) | — | 1.0 | — |

Table 3 illustrates five cases (cases 11 to 15) which show the effect of using pure STC coolant. Exemplary molar ratios range from 2:1 to 20:1. Below about 2:1, the required feed temperature approaches the dew point (e.g., the dew point is 92.9° C. at a molar ratio of 2.3:1). The dew point represents the approximate lowest possible input temperature for the feed, since the feed should enter the reactor substantially in a gas phase so as to prevent reactor cold spots and related operational issues.

TABLE 3

| | Reactor | Reactor | Reactor |
|---|---|---|---|
| | Feed | Feed | Product |
| | Dew Point | Temperature | Temperature |
| | (° C.) | (° C.) | (° C.) |
| | CASE 11 | | |
| VapFrac | 1.00 | 1.00 | 0.99989 |
| T [C.] | 104.7 | 276.4 | 320.0 |
| P [bar(g)] | 3.00 | 3.00 | 3.00 |
| Mole Flow [kgmole/h] | 500.00 | 500.00 | 490.30 |
| MoleFlows [kgmole/h] | | | |
| MoleFlows. HYDROGEN | 0 | 0 | 10.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 470.00 | 470.00 | 470.75 |
| TETRACHLORIDE | | | |
| MoleFlows.Gsilicon | 0 | 0 | 0.05 |
| Molar Ratio (Diluent:HCl) | — | 15.7 | — |
| | CASE 12 | | |
| VapFrac | 1.00 | 1.00 | 0.99987 |
| T [C.] | 104.0 | 264.8 | 320.0 |
| P [bar(g)] | 3.00 | 3.00 | 3.00 |
| Mole Flow [kgmole/h] | 400.00 | 400.00 | 390.30 |
| MoleFlows [kgmole/h] | | | |
| MoleFlows. HYDROGEN | 0 | 0.00 | 10.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 370.00 | 370.00 | 370.75 |
| TETRACHLORIDE | | | |
| MoleFlows.Gsilicon | 0 | 0 | 0.05 |
| Molar Ratio (Diluent:HCl) | — | 12.3 | — |
| | CASE 13 | | |
| VapFrac | 1.00 | 1.00 | 0.99982 |
| T [C.] | 102.9 | 244.9 | 320.0 |
| P [bar(g)] | 3.00 | 3.00 | 3.00 |
| Mole Flow [kgmole/h] | 300.00 | 300.00 | 290.30 |
| MoleFlows [kgmole/h] | | | |
| MoleFlows. HYDROGEN | 0 | 0 | 10.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 270.00 | 270.00 | 270.75 |
| TETRACHLORIDE | | | |
| MoleFlows.Gsilicon | 0 | 0 | 0.05 |
| Molar Ratio (Diluent:HCl) | — | 9.0 | — |
| | CASE 14 | | |
| VapFrac | 1.00 | 1.00 | 0.99973 |
| T [C.] | 100.6 | 202.3 | 320.0 |
| P [bar(g)] | 3.00 | 3.00 | 3.00 |
| Mole Flow [kgmole/h] | 200.00 | 200.00 | 190.30 |
| MoleFlows [kgmole/h] | | | |
| MoleFlows. HYDROGEN | 0 | 0 | 10.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 170.00 | 170.00 | 170.75 |
| TETRACHLORIDE | | | |
| MoleFlows.Gsilicon | 0 | 0 | 0.05 |
| Molar Ratio (Diluent:HCl) | — | 5.7 | — |
| | CASE 15 | | |
| VapFrac | 1.00 | 1.00 | 0.99943 |
| T [C.] | 92.9 | 95.0 | 363.9 |
| P [bar(g)] | 3.00 | 3.00 | 3.00 |
| Mole Flow [kgmole/h] | 100.00 | 100.00 | 90.30 |
| MoleFlows [kgmole/h] | | | |
| MoleFlows. HYDROGEN | 0 | 0 | 10.50 |
| MoleFlows. HYDROGEN | 30.00 | 30.00 | 0 |
| CHLORIDE | | | |
| MoleFlows. | 0 | 0 | 0 |
| DICHLOROSILANE | | | |
| MoleFlows. | 0 | 0 | 9.00 |
| TRICHLOROSILANE | | | |
| MoleFlows. SILICON | 70.00 | 70 | 70.75 |
| TETRACHLORIDE | | | |
| MoleFlows.Gsilicon | 0 | 0 | 0.05 |
| Molar Ratio (Diluent:HCl) | — | 2.3 | — |

In cases 1-15 in Tables 1 to 3, the HCl feed rate is held constant and 100% of it is reacted to silicon products in the chlorinator. Also, the operating temperature of the chlorinator is maintained at 320 degrees centigrade by adjusting coolant temperature, and the operating pressure in all cases is 3 barg.

The process of the present disclosure may be run in such a way that the HCl and the coolant are in admixture before they enter the reactor. However, whether or not they are in admixture, in various embodiments, the HCl and the coolant may enter the reactor at a molar ratio of coolant:HCl of 2:1 to 20:1, or 3:1 to 18:1, or 4:1 to 16:1, or other ratios as disclosed herein.

It is noted that the dew point is a function not only of composition (e.g., higher hydrogen content raises the dew point, whereas higher STC content lowers the dew point), but of system operating pressure. Higher operating pressure lowers the dew point for any given mixture—and vice versa. Tables 1-3 are based on 3 barg because this is the pressure at which direct chlorination reactors are typically operated. However, the process of the present disclosure is flexible and can utilize other operating pressures as described elsewhere herein, including any given concentrations of the coolant mixture, any given pressure of the direct chlorination reactor, and any given molar ratio of coolant to HCl in the direct chlorination reactor feed. The chloride acceptor is metallurgic silicon in these examples, and it is fed to the chlorinator at 200° C. because that temperature is typically used in chlorination reactions. However different temperatures can be used—both higher and lower, in the process of the present disclosure. For example, the temperature of the chloride acceptor may be as low as 50° C., or 80° C., or 100° C., or 130° C., or 160° C., or 180° C. or 220° C. The upper temperature may be 300° C., or 280° C., or 260° C., or 250° C., 240° C., or 230° C., or 220° C., or 200° C., or 180° C., or 160° C., or 140C. Suitable ranges may be therefore be, for example, 180-220° C., or 160-240° C., or 140-280° C.

Relevant factors to consider in selecting input conditions to the reactor include the following: (a) The feed should be maintained above its dew point. For a given temperature, this may be accomplished, for example, by adding more coolant to the feed thereby increasing the ratio of coolant to HCl; (b) A suitable amount of coolant should be used so that the chlorination reactor does not become too large for a given required hold up time (typically on the order of 50 seconds); (c) The feed temperature should be selected so that the chlorination reactor runs within a desired operating temperature range.

In one aspect, the process of the present disclosure additionally includes operating the reactor in a semi-batch or continuous mode and/or as a fluidized bed reactor. The reactor may operate in a semi-batch or a continuous mode. In a semi-batch mode, the chloride acceptor, e.g., metallurgic silicon, is introduced into the reactor and maintained therein for a desired period of time, while chloride donor, e.g., HCl, is fed to the reactor, and gaseous reaction products are continuously withdrawn from the reactor. At the end of the desired period of time, the residual metallurgic silicon feedstock is withdrawn from the reactor, and a fresh metallurgic silicon feedstock is introduced into the reactor. Typically, the temperature and pressure within the reactor, when operated in a batch mode, will undergo significant fluctuation as the metallurgic silicon material is introduced and then withdrawn from the reactor. In a continuous mode, chloride acceptor and chloride donor are substantially, continuously fed to the reactor, and gaseous reaction products are continuously recovered from the reactor. In a continuous mode operation, the reactor is constantly maintained within a desired temperature and pressure range.

The reactor may be a fluid (a.k.a. fluidized) bed reactor. In one embodiment, the MGSi provides the particles which form the fluidized bed, however the bed may instead be formed from small metallic particles. The chloride donor, e.g., HCl, may enter the reactor via an inlet tube directed into the base of the reactor below the distributor tray. The chloride acceptor, e.g., MGSi, may be added through a dip tube descending into the upper part of the reactor, the middle of the reactor, or the lower part of the reactor but above the distributor tray. In addition to one or more inlets, the reactor has at least one outlet so that materials can be constantly fed into the reactor and allowed to exit the reactor.

In one aspect, the process of the present disclosure additionally includes introducing a chloride donor to the chlorinator under input condition. The input conditions describe the conditions of the chloride donor as it enters the chlorinator. For example, the donor may be in the gas phase. The donor may be at a temperature within the range of 30-450° C., 250-450° C., 250-400° C., 250-350° C., 300-450° C., 350-450° C., 300-400° C., 300-350° C., or 350-400° C. The donor may be under a pressure of 1-10 barg, 1-8 barg, 1-6 barg, 2-10 barg, 2-8 barg, or 2-6 barg. The donor may be pure, or it may be in combination with one or more other components such that the donor constitutes less than 50 mole %, or at less than 45%, or less than 30%, or less than 20%, or less than 15%, or less than 10%, or less than 5% of the material input into the reactor, on a molar basis. As mentioned elsewhere herein, the chloride donor may be HCl. Optionally, the donor may be in admixture with the coolant as they both simultaneously enter the chlorinator. In this case, the temperature and pressure of the admixture may be any of the values provided herein for the admixture components, i.e., the chloride donor and the coolant.

In one aspect, the process of the present disclosure additionally includes introducing a chloride acceptor to the chlorinator under input condition. The input conditions describe the conditions of the chloride acceptor as it enters the chlorinator. A preferred chloride acceptor is MGSi, and the input conditions to the chlorinator for the chloride acceptor will be illustrated by reference to MGSi. In general, the chloride acceptor will contain silicon as it is introduced to the reactor. The chloride acceptor will contain silicon and chloride as it exits the reactor. In one embodiment, the chloride acceptor is metallurgic silicon (MGSi) of at least 95%, or at least 97%, or at least 98%, or at least 99% purity. The MGSi is a particulate material that may be added to the reactor at ambient or elevated temperature and pressure. Within the chlorinator, the MGSi may be present in molar excess compared to the presence of the chloride donor within the reactor. The MGSi may not only function as the chloride acceptor, it may also function as the bed material in forming a fluidized bed within the reactor.

In direct chlorination, the transfer of chloride from the chloride donor to the chloride acceptor is an exothermic reaction. The exothermic heat of reaction is transmitted, at least in part and optionally in full, to the internal coolant that is in admixture with the reactant(s) and product(s) of the chlorination reaction. Some of the heat may optionally be transmitted directly to the environment or to external coolant. This may occur when the reactor shell is incompletely insulated, so that heat can escape from the reactor to the environment. This may also occur when cooling coils are allowed to contact the reactor and/or the contents of the reactor, where the cooling coils contain circulating or otherwise moving coolant that absorbs heat from the walls of the cooling coil and then carries away that heat to the environment. The process of the present disclosure provides that the heat of reaction is transferred to the environment and/or external coolant in minor part, in other words, no more than 50%, or no more than 40%, or no more than 30%, or no more than 25%, or no more than 20%, or no more than 15%, or no more than 10%, or no more than 5% of the heat of reaction is transferred to the environment and/or external coolant. This is in contrast to conventional chlorination reactors where at least 50% of the heat of reaction is transferred to external coolant. For example, internal cooling coils, or external cooling jackets are utilized in conventional chlorination reactors to achieve cooling of the reactor contents. The present process avoids or minimizes the use of cooling equipment in favor of utilizing an internal cooling fluid which is in admixture with the chloride acceptor and chloride donor to control the rate of heat production, and then matching that rate of heat production to the rate of heat transfer to the internal cooling fluid.

Optionally, the reactor may include external cooling means such as coils located either inside or on the surface of the reactor, where those coils contain circulating cooling fluid. However, in this situation, these cooling means absorb a minor amount of the heat generated within the reactor. In embodiments, the external cooling means absorb less than 50%, or less than 40%, or less than 30%, or less than 25%, or less than 20%, or less than 15%, or less than 10%, or less than 5% of the heat generated within the reactor. The presence of cooling coils may be useful in those unexpected situations where some additional fine tuning of the temperature within the reactor is desired. However, in the ordinary course, fine tuning of the temperature within the reactor is accomplished by adjusting the input conditions of the feedstock to maintain reactor temperature within a specified range.

The reactor may contain coils that are used to transmit heated fluid, in order to warm up the reactor and its contents to a temperature sufficient to initiate the chlorination reaction.

When the chlorinator is operating under adiabatic or near adiabatic conditions, the input conditions for the chloride donor, the chloride acceptor, and cooling fluid added therewith, are selected in view of the innate ability of the reactor to passively dissipate heat to the environment. In other words, once the desired reactor operating conditions are selected, e.g., 2-4 barg pressure and 275-325° C., input conditions for the chloride acceptor, donor and cooling fluid are selected in order to achieve these operating conditions, keeping in mind that the reactor may have an innate ability to dissipate heat, particularly if the reactor is not completely isolated from the environment.

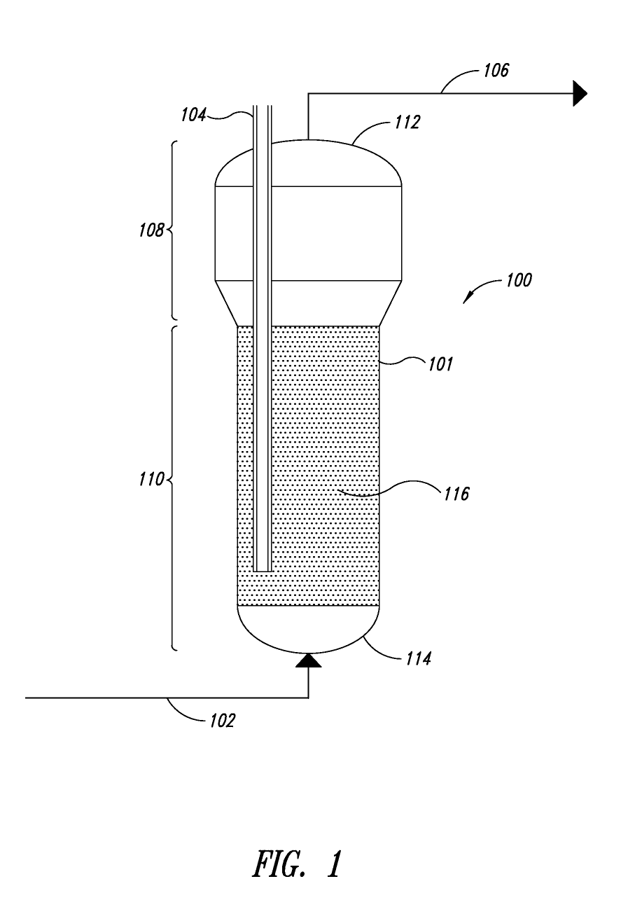

An exemplary chlorinator and its operation are illustrated by reference to FIG. 1. In FIG. 1, a reactor 100 is disposed in a vertical fashion. The reactor 100 may be generally cylindrical, as shown in FIG. 1. The reactor 100 is made from a reactor shell 101 comprising a sturdy material which can withstand elevated temperature, pressure and contact with corrosive materials. Such materials are well known in the art, and include carbon steel. Two conduits, namely conduit 102 and conduit 104, provide a means for introducing reactants to the reactor 100, while one conduit, namely conduit 106, provides a means for removing products from the reactor 100. The reactor 100 has an upper region 108 and a lower region 110, as well as a reactor top 112 and a reactor bottom 114. A fluidized bed 116 occupies the major part of the lower region 110 of the reactor 100, while the upper region 108 of the reactor 100 is largely open space and may be referred to as a calming zone. The conduit 102 connects to the bottom 114 of the reactor 100 and allows introduction of reactants into the bottom of the fluidized bed 116. The conduit 104 enters the top 112 of the reactor 100 and continues through the fluidized bed 116 until the conduit 104 terminates within the fluidized bed, preferably in the mid to lower region of the fluidized bed 116 of the reactor 100.

The upper region 108 and lower region 110 are adjacent to one another, as shown in FIG. 1. When the reactor 100 is generally cylindrical, each of the upper region 108 and lower region 110 will have a diameter. In one embodiment, the diameter of the upper region 108 is greater than the diameter of the lower region 110, as shown in FIG. 1. When fluidized bed technology is employed in a vertically disposed reactor, the fluidized bed will be located in the lower region 110. In FIG. 1, the fluidized bed is illustrated by the black specks 116. Optionally, the reactor 100 could be a cylinder of constant diameter for its entire length with an internal or external cyclone instead of a larger diameter calming zone in the upper region 108.

The reactor 100 is in fluid communication with a conduit 102 and a conduit 104, both used to introduce reactants to the reactor 100, and a conduit 106 used to permit egress of product from the reactor 100. Both of the conduits 102 and 104 may be used to introduce feedstock material to the reactor. For example, the conduit 102 and the conduit 104 may introduce feedstock material into a fluidized bed 116 that is present within the lower region 110 of the reactor 100. In a preferred embodiment the conduits 102 and 104 introduce feedstock materials into a region of the fluidized bed 116 that is located approximately half way down the lower region 110, or more than half way down the lower region 110. The conduit 102 may be used to introduce a gas phase feedstock including a chloride donor, while the conduit 104 may be a feeder dip-tube that is useful for introducing a particulate feedstock including a chloride acceptor, to the fluidized bed 116 within reactor 100. The conduit 106 is useful in allowing egress of the gaseous product mixture from the reactor 100, where the conduit 106 may be in fluid communication with the reactor 100 at the upper region 108 of the reactor, optionally at the top 112 of the reactor 100 as shown in FIG. 1, or at some other location near the top 112 of the reactor 100.

With the configuration of reactor 100 and conduits 102, 104 and 106 as shown in FIG. 1, feedstock materials enter a fluidized bed 116 near the bottom 114 of the lower region 110 of the reactor 100, and then undergo chemical reaction while moving upwards towards the top of the reactor 112. As the gas feedstock(s) travel through the fluidized bed 116, they react with the chloride acceptor so as to form a product mixture that enters into the upper region 108, which acts as a solid de-entrainment zone, whereupon the product mixture exits the reactor via conduit 106. The conduits 102, 104 and 106 may be prepared from material that is suitable to withstand elevated temperature and pressure, as well as corrosive materials, where carbon steel is one such suitable material.

The reactor 100 in FIG. 1 is shown in a preferred embodiment, lacking any external cooling means such as a cooling coil or a cooling jacket. The reactor 100 may, however, include such external cooling means, even though such means are not necessary for the chlorination processes of the present disclosure. Nevertheless, the reactor may include such external cooling means even though they are not utilized to achieve cooling when performing the chlorination process of the present disclosure, or are present only to provide a minimal amount of cooling, or are present only as an optional cooling means available for use in unconventional situations, e.g., an emergency. Thus, while in a preferred embodiment the reactor lacks cooling surfaces in contact with the reactor shell or the reactor contents, such cooling surfaces may optionally be present.

In one aspect, the chloride donor is present as a part of the effluent that is generated by one or more STC converters. In other words, the STC converter(s) may be a single converter or a multiplicity of converters acting in parallel and/or series. For example, the entirety of the effluent from an STC converter may be directed into the chlorinator, although in other embodiments, at least 95 wt. %, or at least 90 wt. %, or at least 85 wt. %, or at least 80 wt. % or at least 75 wt. %, or at least 70 wt. %, or at least 65 wt. %, or at least 60 wt. %, or at least 55 wt. % or at least 50 wt. % of that effluent is directed into the chlorinator. Although, as just mentioned, less than 100% of the effluent from an STC converter may be used as a feedstock for the chlorinator, it should be noted that in any event it is not necessary to select a particular composition of effluent to enter the chlorinator as a feedstock. In other words, it is not necessary and preferably does not occur that the composition of the effluent from the STC converter is altered by purification or refinement into a different composition. A notable feature of an embodiment of the present process is that the crude effluent from an STC converter may be used directly as the feedstock for the chlorinator. This is advantageous because the use of crude effluent avoids the undesirable capital costs and operating expenses of a refinement system that might be used to purify/fractionate the crude effluent into a different composition. Along these lines, it may be mentioned that in one embodiment, the crude effluent is combined with one or more additional gas streams, termed the auxiliary gas streams. An auxiliary gas stream may comprise chloride donor, for example, HCl.

The STC converter receives STC and converts it, in whole or part, to an effluent comprising TCS and HCl, where HCl is a chloride donor. In optional embodiments, the effluent may also comprise, for example, one or both of hydrogen (H₂) and STC. The STC converter may be operated in an equilibrium or a non-equilibrium mode, and it may likewise be operated in catalytic or thermal (i.e., non-catalytic) mode. Thus, the STC converter may be operated in tandem with the chlorinator, in which case for convenience the STC converter may be referred to as the 1^{st} stage reactor, and the chlorinator may be referred to as the 2^{nd} stage reactor.

STC converters are well known in the art, and are presently operating in silicon producing facilities around the world. The STC converter in the foregoing description may be a standard hot converter (i.e., one that runs at high temperatures, as high as 900° C. to 1300° C.), or more preferably a low temperature, catalytic converter (that runs in the range of 300° C. to 700° C.). Accordingly, the effluent from the STC converter may likewise be in the range of 300° C. to 1300° C., depending on how the STC converter is operated. When it is desired to feed this 1st stage effluent into a 2nd stage reactor that is operating at a temperature below the temperature of the 1^{st} stage effluent, it is desirable to cool the effluent from the 1st stage reactor using a cooling unit. In embodiments, the effluent from the 1st stage reactor is cooled to a temperature within one of the following ranges: 75-400° C., 125-400° C., 200-400° C., 150-350° C., 200-350° C., 150-300° C., 200-300° C., 150-250° C., 200-250° C., about 200° C., i.e., 175-225° C. After cooling, the effluent from the 1st stage reactor, optionally after combination with one or more auxiliary gas streams, may be directed into a 2nd stage reactor. The 2^{nd} stage reactor may be optionally operated at a temperature in excess of the temperature of the effluent from the 1st stage reactor, or optionally of the cooled effluent from the 1^{st} stage reactor. Optionally, the cooling unit may comprise a heat interchanger, using the heat in the 1^{st} stage reactor off-gas to pre-heat the feed to the 1^{st} stage reactor.

By using the entire (or at least most of the) unrefined effluent from an STC converter as all or part of the feedstock for a chlorinator as disclosed herein, and by adjusting, as necessary, the temperature of that effluent to a temperature as described above, e.g., about 200° C., the heat capacity of the 1^{st} stage effluent and the mass of the 1^{st} stage effluent combine to absorb the heat produced during the chlorination reaction that takes place in the 2^{nd} stage chlorination reaction, thereby limiting the temperature rise in the 2^{nd} stage reactor. As a result, the effluent from the 2^{nd} stage reactor has a temperature of, for example, about 320° C., without recourse to any external cooling means, e.g., cooling coils. The combination of controlled chlorination reactor feed temperature and higher molar flow rate, due to the addition of coolant as described elsewhere herein, which is higher than that used in conventional direct chlorination reactors per mole of chloride donor in the feed, is advantageous in that it reduces the potential for the formation of hot spots within the reactor.

In one aspect, the present disclosure provides a process comprising:
a. introducing STC and hydrogen into a 1^{st} stage reactor and expelling a first product gas comprising TCS and HCl from the 1^{st} stage reactor; and
b. introducing the first product gas and MGSi into a 2^{nd} stage reactor and expelling a second product gas comprising hydrogen and additional TCS from the 2^{nd} stage reactor;
where unrefined first product gas from the 1^{st} stage reactor is delivered to the 2^{nd} stage reactor.

In analogy, the present disclosure also provides a system comprising:
a. a 1^{st} stage reactor wherein STC and hydrogen are introduced and a first product gas comprising TCS and HCl are expelled; and
b. a 2^{nd} stage reactor in fluid communication with the 1^{st} stage reactor, where the first product gas and MGSi are introduced into the 2^{nd} stage reactor and a second product gas comprising hydrogen and additional TCS is expelled from the 2^{nd} stage reactor;
where the 1^{st} stage reactor delivers unrefined first product gas to the 2^{nd} stage reactor.

The systems and methods of the present disclosure may include a temperature control unit, also known as a temperature controller. In general, temperature control can be achieved by many methods, and the design, manufacture and operation of temperature controllers is well known in the art. Heat exchangers, cooling towers, chillers, boilers, electric and other types of heaters, and heat pumps are a few of the well-known temperature controllers used in industrial processes, any of which may be used in the systems and methods of the present disclosure. Temperature controllers may be used to cool a fluid or to heat a fluid, including heating or cooling to convert between gaseous and liquid states. For example, a vaporizer may be used to heat a liquid fluid to a gaseous state. Temperature control may be achieved with a heat exchanger. Heat exchangers are commercially available the plate, spiral and shell-and-tube varieties, any of which may be used to provide heat exchange.

The systems and methods of the present disclosure may include an off gas recovery system. The off gas recovery system receives a mixture of gases and refines that mixture to provide product gas(es) that are enriched in one or more of the components of the original mixture. The off gas recovery system may have multiple components. For example, a separator may be part of an off gas recovery system. A separator acts on a mixture of component parts of a feedstock to separate the components from one another. The design and operation of a separator will depend on the physical properties of the component that is being utilized to achieve the separation, and the component that is being separated. For example, the separator may be able to separate the component parts based on the boiling points of the components. In this case, the separator is commonly called a distillation unit. The design, manufacture and operation of distillation units, also known as distillation columns, is well known in the art. A distillation column typically achieves separation of component gases based on the difference in the boiling points of the components, and is conveniently in the form of a column. A decanter is another type of separator which may be used to separate liquids condensed from a non-condensable gas stream (e.g., hydrogen). Decanters are normally designed for continuous operation. A great variety of vessel shapes is used for decanters, but for most applications a cylindrical vessel will be suitable, and will be the cheapest shape. Typical designs are the vertical decanter and the horizontal decanter. The feedstock may be cooled in order to achieve liquefaction of all or much of the condensable components of the feedstock. A refrigerator/decanter unit refers to a decanter which is in fluid communication with a refrigeration unit such that the condensable components in the feedstock going to the decanter are cooled to a liquid state. The design, manufacture and operation of decanters are well known in the art. The off gas recovery system may include an HCl recovery column which functions to separate hydrogen chloride from chlorosilanes using distillation. Distillation is a method of separating mixtures based on differences in those components boiling temperature at the same pressure. This is a physical separation process where no chemical reaction occurs. Furthermore, this may be a continuous distillation process in which the liquid mixture is continuously fed into the process and the separated fractions are removed continuously as output streams as time passes during the operation. Continuous distillation produces at least two output fractions, including at least one overhead distillate fraction and one bottom fraction. The distillate fraction being the lighter component that boils at a lower temperature is removed as a vapor and the bottoms fraction which boils at a higher temperature is removed from the bottom as a liquid. A distillation column may be employed to separate one or more components from a mixture on the basis of boiling point. A distillation column heats the mixture such that the more volatile components are separated from the less volatile components.

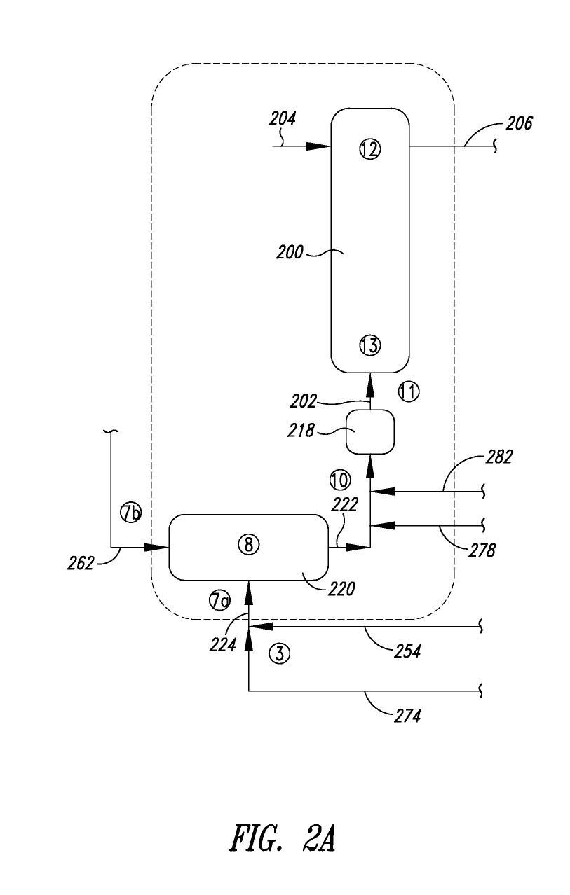

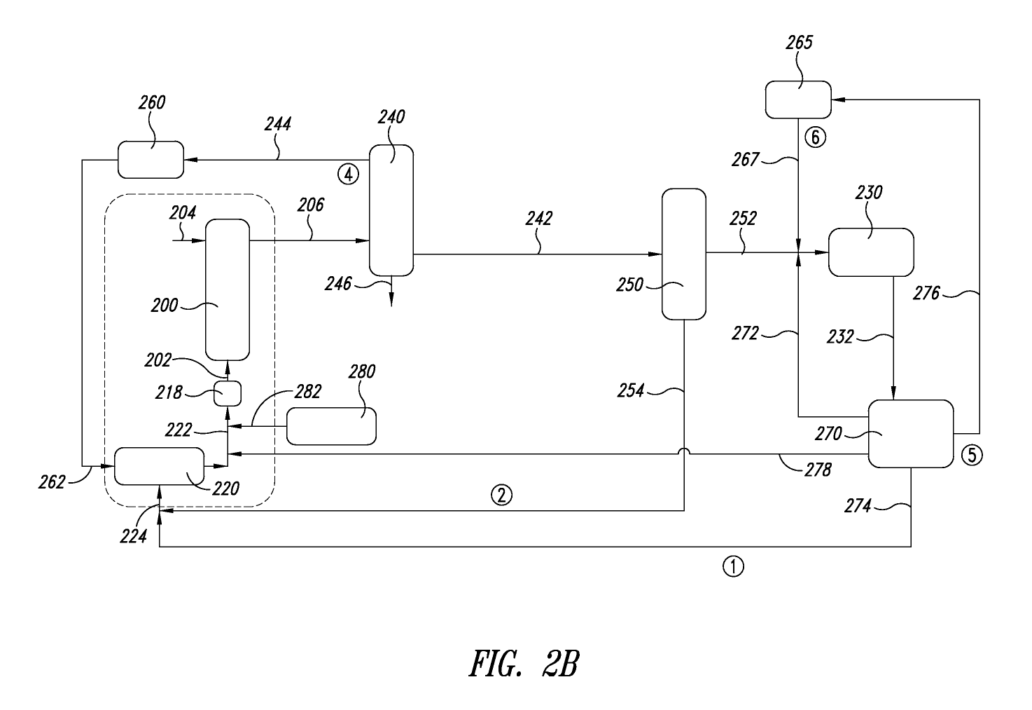

A chlorinator in tandem combination with an STC converter, i.e., a 2^{nd} stage reactor in combination with a 1^{st} stage reactor, respectively, is illustrated in FIG. 2A. The incorporation of the 1^{st} and 2^{nd} stages reactors into an exemplary plant for producing polysilicon is illustrated in FIG. 2B, where the region within the dashed line of FIG. 2B is reproduced in expanded form in FIG. 2A for ease of viewing. In the following description, reference to FIG. 2 means a reference to both of FIG. 2A and FIG. 2B. The chlorinator 100 from FIG. 1 is shown as chlorinator 200 in FIG. 2A and FIG. 2B, where conduits 102, 104 and 106 of FIG. 1 correspond to conduits 202, 204 and 206 of FIG. 2A and FIG. 2B.

In FIG. 2, the 2^{nd} stage reactor 200 receives feedstock gases through conduct 202 directly from the 1^{st} stage reactor 220. As shown in FIG. 2, the entirety of the effluent from 1^{st} stage reactor 220 exits the reactor 220 through conduit 222 and then travels from conduit 222 into conduit 202 and then into the 2^{nd} stage reactor 200. Optionally, although not shown, some of the effluent from the 1^{st} stage reactor 220 may be diverted to other locations within an operating plant. Also optionally, and as discussed later herein, one or more auxiliary gases may be added to the effluent from the 1^{st} stage reactor 200 prior to that effluent being introduced into the 2^{nd} stage reactor 200. In a preferred embodiment, the effluent from 1^{st} stage reactor is not refined or otherwise treated in order to fractionate the effluent or in any way remove one or more components of the effluent from other components of the effluent. In another words, although not all of the effluent from the 1^{st} stage reactor necessarily goes into the 2^{nd} stage reactor, and while some gas(es) may be added to the effluent between its exit from the 1^{st} stage reactor 220 and its entrance into the 2^{nd} stage reactor 200, in a preferred embodiment there is no separation of components of the effluent from one another.

In one embodiment, which is shown in FIG. 2, a temperature controller 218 may be located between the conduit 222 and the conduit 202 in order to adjust the temperature of the contained gas to a temperature approximately equal to the selected operating temperature of the 2^{nd} stage reactor 200, which could advantageously be done during reactor startup. However, once the chlorination reaction has been initiated, the temperature controller 218 may be used to lower the temperature of the feed gas entering the chlorination reactor 200 to a value such that the (cooled) feed gas will absorb the excess heat generated by the chlorination reaction and allow the reactor 200 to be maintained at a constant operating temperature.

The 1^{st} and 2^{nd} stage reactors of FIG. 2A may be incorporated into a plant that produces polysilicon, e.g., a plant that operates the Siemens process in a CVD reactor 230 as shown in FIG. 2B, where FIG. 2B provides a schematic view of an exemplary approach to incorporating the 1^{st} and 2nd stage reactors into a plant that produces polysilicon. In FIG. 2B, the conduits and operating units of FIG. 2A are shown in minimized form within the area enclosed by the dashed line. In brief, as shown in FIG. 2, the 2^{nd} stage reactor 200 produces an effluent that exits the reactor 200 and enters an off-gas recovery system 240 via conduit 206. Selected off-gas from the off-gas recovery system 240 exits the system 240 and enters a TCS refining unit 250 via conduit 242. Selected off-gas from the TCS refining unit 250 exits the refining unit 250 and enters a CVD reactor 230 via conduit 252.

The off-gas recovery system 240 separates components of the effluent that exits reactor 200. That effluent is typically composed of hydrogen, dichlorosilane (DCS), trichlorosilane (TCS), and silicon tetrachloride (STC) with either no or a de minimis amount of hydrogen chloride. The effluent components may be separated by condensation and/or distillation, i.e., by taking advantage of the difference in the boiling points of the effluent components. The fraction having the lowest boiling point, which consists primarily of hydrogen, exits the off gas recovery system 240 through conduit 244 and may be recycled to the 1^{st} stage reactor as discussed below. The fraction having the highest boiling point, which contains short-chain polysilicon compounds and other high boiling waste material, exits the off-gas recovery system 240 through conduit 246 and is ultimately sent to waste treatment. The fraction having an intermediate boiling point, which consists primarily of dichlorosilane (DCS), trichlorosilane (TCS) and silicon tetrachloride (STC), exits the off-gas recovery system 240 through conduit 242 and enters the TCS refining unit 250.

The TCS refining unit 250 as shown in FIG. 2B may be a distillation unit which fractionates DCS, TCS and STC on the basis of the differences in the boiling points of these three components. The highest boiling fraction (the fraction with the highest boiling point) will be purely, or at least enriched in, STC, and will exit the TCS refining unit 250 via conduit 254. This conduit 254 is optionally in fluid communication with the 1^{st} stage reactor, as shown in FIG. 2B, so that refined STC from the TCS refining unit 250 may be used as a feedstock for the STC converter (1^{st} stage reactor) 220. In FIG. 2B, the conduit 254 is seen to feed into conduit 224 which provides entry into the 1^{st} stage reactor 220. The lower boiling fraction from the TCS refining unit 250 will be purely, or at least enriched in, DCS and TCS. Both of DCS and TCS are suitable feedstocks for a CVD reactor operating the Siements process, i.e., CVD reactor 230 in FIG. 2B. Accordingly, the lower boiling fraction from TCS refining unit 250 may be introduced into a CVD reactor 230 via a suitable conduit, e.g., conduit 252 shown in FIG. 2B.

As mentioned previously, the off-gas recovery system 240 separates components of the effluent that exits reactor 200, and that effluent is typically composed of hydrogen, DCS, TCS and STC, and either little or no hydrogen chloride. The gas recovery system 240 separates these components by condensation and/or distilling them, and the fraction having the lowest boiling point, which consists primarily of hydrogen, exits the off gas recovery system 240 through conduit 244. Conduit 244 delivers the hydrogen into a compressor 260 which compresses the gas into a higher pressure, lower volume form. The compressed gas exists the compressor 260 and is delivered into the 1^{st} stage reactor 220 through a conduit 262. Overall, as seen in FIG. 2B, the present disclosure provides a system and process wherein hydrogen may be continuously recycled in turn through a 1^{st} stage reactor 220 (an STC converter), a 2^{nd} stage reactor 200 (a chlorination reactor), an off-gas recovery system 240, and then back into the STC converter 220.

The CVD reactor 230 will generate polysilicon and an off gas that exits the reactor 230 and enters an off gas recovery system 270 through conduit 232. The off gas from the CVD reactor 230 typically consists of hydrogen, hydrogen chloride, DCS, TCS and STC. The off gas recovery system 270 separates the components of this off gas on the basis of boiling point. For example, the component with the lowest boiling point temperature will consist primarily of hydrogen, and will exit the system 270 via conduit 276. This hydrogen will enter a hydrogen compressor 265 and the resulting compressed hydrogen travels to the CVD reactor 230 via conduit 267 which feeds into conduit 252.

Optionally, although not shown in FIG. 2B, conduit 276 may feed into conduit 244, which also carries hydrogen (from off gas recovery unit 240), and the combined fractions may be delivered into the compressor 260. Typically, a relatively small amount (if any) of the hydrogen which leaves the off gas recovery system 270 will enter the hydrogen compressor 260.

The next highest boiling fraction from off gas recovery system 270 will consist primarily of hydrogen chloride, and it will exit the system 270 via conduit 278. Conduit 278 may feed into conduit 222 (as shown) or conduit 202 (not shown), which also carries hydrogen chloride, and the combined fractions may be delivered into the 2^{nd} stage reactor 200. The next highest boiling fraction will consist primarily of DCS and TCS, and this fraction will exit system 270 via conduit 272. Conduit 272 may feed into conduit 252, which also carries DCS and TCS (from the TCS refining unit 250), and the combined fractions may be delivered into the CVD reactor 230. The lowest boiling fraction will consist primarily of STC, and this fraction will exit system 270 via conduit 274. Conduit 274 may feed into conduit 224 and thereby provide a source of STC for the 1^{st} stage reactor (STC converter) 220.

In addition to, or in the alternative to, obtaining hydrogen chloride from the off gas recovery system 270, the 2nd stage reactor 200 may obtain hydrogen chloride from a tank of hydrogen chloride. For example, the plant operator may purchase a pressurized tank of hydrogen chloride, shown as the HCl reservoir 280 in FIG. 2B. A conduit 282 leading from HCl reservoir 280 may feed into conduit 220 from the 1^{st} stage reactor, to thereby provide a feedstock enriched in hydrogen chloride that may be delivered into the 2^{nd} stage reactor 200 via conduit 202.

Optionally, and not shown in FIG. 2A or 2B, is an embodiment of the present disclosure wherein any one or more of the conduits 282, 278, 254 and 274 are in contact with a temperature controlling means to either heat or cool the contents of the conduit. For example, a heater may be in contact with either one or both of conduit 282 from the HCl reservoir 280 and conduit 278 from the off gas recovery system 270, to bring the temperature of the chloride donor from an HCl source to an elevated temperature at or near the operating temperature of 2^{nd} stage reactor 200. As another embodiment, HCl and a coolant as described previously may be combined and the resulting admixture is directed into a cooling unit that adjusts the temperature of the admixture to a desired temperature which is selected to absorb the excess heat generated by the chlorination reaction.

As mentioned previously, the 1^{st} stage reactor 220 (STC converter) is connected directly or indirectly (via conduit 224) to conduit 262, conduit 254 and conduit 274, where any one or more of the conduits may deliver feedstock(s) to the reactor 220. Such feedstock(s) include STC and H₂. In various embodiments, the feedstock(s) may be combined to create an admixture within the 1^{st} stage reactor 220; and the feedstock(s) may be combined to create an admixture having an H₂:STC molar ratio, where in various embodiments this H₂:STC molar ratio may be in the range of 0.1:1 to 10:1, or 0.5:1 to 5:1, or 1:1 to 4:1 or 1.5:1 to 3.5:1 or 2:1 to 3:1. In addition, the 1^{st} stage reactor 220 may be in contact with temperature control means, not shown in FIG. 2, e.g., a temperature control means whereby heat may be introduced to or withdrawn from the 1^{st} stage reactor 220 or optionally to the feeds to the 1^{st} stage reactor 220. By proper control of the ratio of gases introduced by conduits 262, 254 and 274, the 1^{st} stage reactor 220 may be run isothermally.

The operational units shown in expanded form in FIG. 2A, when viewed as a combined process, provide for the feed to and the product exiting from the combined reactors 200 and 220 to be very similar to the feed to and the product exiting from a hydrochlorination reactor. The difference is in the operational units inside the system. The high pressure, high temperature, and high hold-up time required by a traditional hydrochlorination reactor are lowered, because the 2^{nd} stage chlorination step runs at low pressure (e.g., about 5 barg), low temperature (e.g., about 320° C.), and low hold-up time (e.g., about 50 seconds) because STC is pre-converted to TCS in reactor 220.

In addition to illustrating the tandem combination of a 1^{st} and 2^{nd} stage reactor as shown in FIG. 2A, an option for incorporating this combination into a plant for making polysilicon is shown in FIG. 2B. The steps of such a process may be described as including the following:
1. Collect STC recycle from a CVD reactor off-gas recovery system 270 optionally including supplemental STC addition (step 1; see encircled “1” in FIG. 2B);
2. Collect STC recycle from the chlorination reactor 200 (a.k.a., “2^{nd} stage reactor”) off-gas recovery system 240 after TCS refining in the TCS refining unit 250 (step 2);
3. Combine STC collected in Steps 1 and 2 to form an STC admixture (step 3);
4. Collect hydrogen recycle from the chlorination reactor (a.k.a., “2^{nd} stage reactor”) off-gas recovery system 240 (step 4);
5. Collect hydrogen recycle from the CVD reactor 230 off-gas recovery system 270 and introduce that hydrogen recycle into a hydrogen compressor (step 5);
6. Route the hydrogen recycle from step (5) into the CVD reactor (step 6);
7. Route the STC (step 7a) and hydrogen (step 7b) formed in Steps 3 and 4, respectively, to an STC converter 220 (a.k.a., “1^{st} stage reactor”), with the hydrogen optionally passing through a recycle hydrogen compressor 260 prior to entering the 1^{st} stage reactor 220;
8. Form an admixture comprising the hydrogen and STC admixtures within the 1^{st} stage reactor 220, for example, in a 1:1 to 4:1 H₂:STC molar ratio (step 8),
9. Optionally and not shown in FIG. 2, the conduit 262 and the conduit 224 may come into fluid communication with one another prior to either conduit contacting the 1^{st} stage reactor 220, in which case an admixture comprising STC and H₂ will be formed within a conduit, and then fed into the STC converter 220 (a.k.a., “1^{st} stage reactor”)(step 9, not shown);
10. To the product stream traveling via conduit 222 which exits the STC converter 220 (a.k.a., “1^{st} stage reactor”) and enters the chlorinator 200 (a.k.a., “2^{nd} stage reactor”) via conduit 202, optionally add supplemental HCl from a chloride reservoir tank 280 and/or a CVD reactor off-gas recovery system 270 to thereby form a combined admixture as shown (step 10);
11. During startup, feed the combined admixture formed in Step 10 to a chlorination reactor 200 (a.k.a. “2^{nd} stage reactor”) (step 11), optionally after adjusting the temperature of the combined admixture to a temperature near the operating temperature of the chlorination reactor 200 with feed temperature controller 218 as discussed below in Step 13;
12. Run the chlorination reactor 200 (a.k.a., “2^{nd} stage reactor”) at a temperature in the range of 250° C. to 450° C., preferably between 300° C. to 350° C., and pressures in the range of 1 barg to 30 barg, preferably between 2 barg and 5 barg (step 12); and
13. Control the temperature of the combined admixture formed in Step 10, which is a feed to the chlorination reactor 200 (a.k.a., “2^{nd} stage reactor”), in the range of 50° C. to 350° C., more preferably at a temperature such that little to no heat removal from the chlorination reactor is required. The temperature may be controlled, for example, by cooling or heating the combined admixture with temperature controller 218 prior to its entry to the 2^{nd} stage reactor 200 in combination with controlling the rate that the combined admixture enters the 2^{nd} stage reactor 200 (step 13).

The tandem operation of the 1st and 2nd stage reactors, as illustrated in FIG. 2, provides for advantageous heat and material balance, as explained by reference to the following example. The feed to the chlorination reactor 200 (a.k.a., “2nd stage reactor”) is comprised of two streams. The first stream (Stream 1), which may enter reactor 200 by way of conduit 202, comprises chloride donor, and may for example, be comprised of 700 moles of hydrogen, 288 moles of STC, 123 moles of TCS, and 123 moles of HCl. The temperature of Stream 1 may be controlled to a temperature of about 183° C. The second stream (Stream 2), which may enter reactor 200 by way of conduit 204, comprises chloride acceptor, and may for example, be comprised of 42 moles of silicon in the form of MGSi. The temperature of Stream 2 is controlled to be between 50° C. and 300° C. The chlorination reactor may be run adiabatically at 320° C. and 3 barg. Within the chlorination reactors 200, essentially all HCl is reacted upon contact with an excess of silicon to produce a product stream, which may exit reactor 200 by way of conduit 206, and comprises hydrogen, STC, TCS, typically some DCS, and de minimis amounts of HCl. By way of example, the gaseous product stream may contain 741 moles of hydrogen, 288 moles of STC, and 164 moles of TCS. The temperature of the gaseous product stream may be about 320° C.

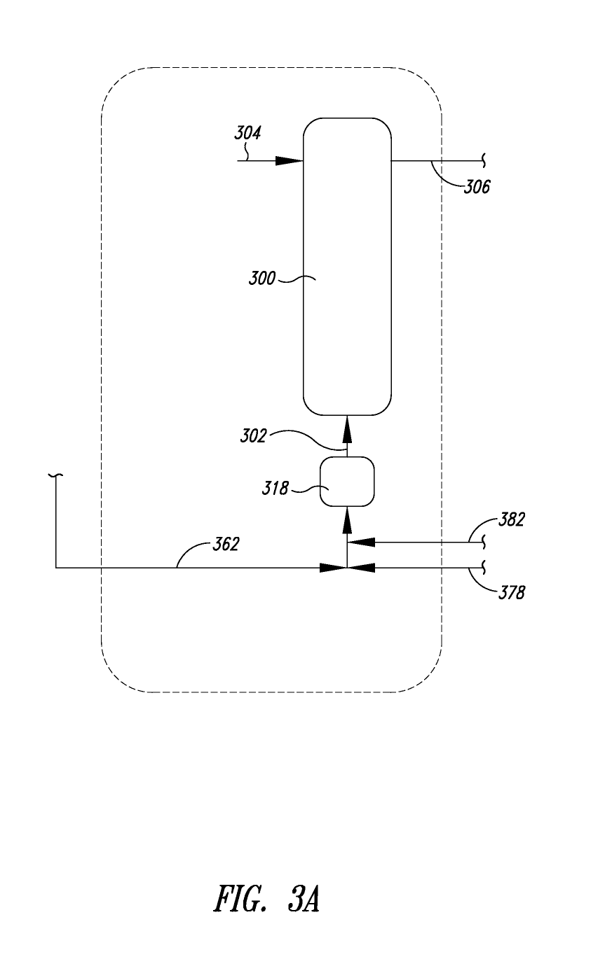

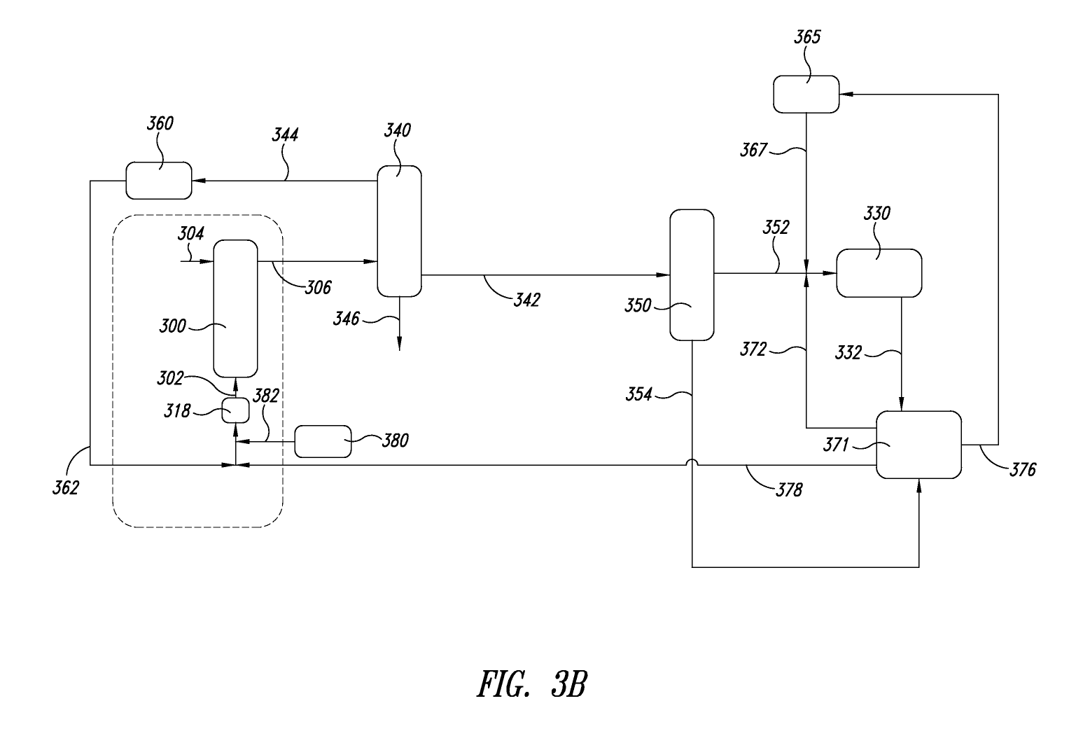

While the present disclosure provides a tandem combination of chlorinator reactor and STC converter, the chlorination process of the present disclosure is not limited to the combination of an STC converter and a chlorination reactor. Feedstock to the chlorinator need not come entirely or even partially from an STC reactor. For example, the feedstock may be an admixture including portions of hydrogen, STC, TCS, and HCl formed from pure materials in sufficient amounts and provided at suitable temperature such that the direct chlorination reactor may be operated at desired operating temperatures without the need for external cooling mechanisms. An exemplary system and operation thereof that does not include the tandem combination of chlorinator reactor and STC converter is illustrated in FIG. 3.

In FIG. 3, the chlorinator of the present disclosure is shown as unit 300. In general, a feature in FIG. 2A or FIG. 2B identified as 2xx will correspond to the same feature in FIG. 3A or FIG. 3B which is identified as 3xx. For example, chlorination reactor 300 in FIG. 3A and FIG. 3B corresponds to chlorination reactor 200 in FIG. 2A and FIG. 2B. A reference to FIG. 3 will be a reference to each of FIG. 3A and FIG. 3B.

In FIG. 3, the chlorinator 300 operates in conjunction with a CVD reactor 330 which produces polysilicon and, as shown in FIG. 3, an off-gas which exits the reactor 330 through conduit 332. The off-gas typically consists of hydrogen, hydrogen chloride, DCS, TCS and STC. The off-gas in conduit 332 may be delivered to an off gas recovery system 371 which includes a unit for converting STC to TCS (i.e., an STC converter is a component of the off-gas recovery system 371; an STC converter was not a component of the off-gas recovery system 270). The off-gas recovery system 371 produces three exit streams: an HCl containing stream which exits the recovery system 371 via a conduit 378, an exit stream comprising TCS which exits the recovery system 371 via a conduit 372, and an exit stream comprising hydrogen which exits the recovery system 371 via a conduit 376. The HCl stream in conduit 378 may be fed into the chlorinator 300, optionally after having its temperature adjusted by means of a temperature controller 318. The TCS stream in conduit 372, which may optionally be in admixture with hydrogen, may be directed back into the CVD reactor 330 to undergo additional conversion to polysilicon. In addition to receiving chloride donor HCl via conduit 378, the chlorinator 300 may receive chloride acceptor via conduit 382 in fluid communication with an HCl storage reservoir 380. An exothermic chlorination reaction occurs within chlorinator 300, with the concomitant formation of an off gas which exits the chlorinator 300 via conduit 306. Optionally, although not shown in FIG. 3, the off gas recovery system may generate an effluent stream comprising STC that is delivered directly to the chlorination reactor 300, where this effluent stream provides a coolant to allow the chlorination reactor 300 to operate under adiabatic conditions. As needed, the STC-containing effluent stream from the off gas recovery system 371 may pass through a temperature controller which brings the temperature of the effluent to a temperature below the operating temperature of the chlorinator 300.

The off-gas from the chlorinator 300 may be refined and/or recycled in various ways, including the process illustrated in FIG. 3B. In FIG. 3B, the off gas in conduit 306 is delivered to a reactor off-gas recovery unit 340. The off gas recovery unit 340 optionally creates one, two or three product streams. One optional product stream, which is shown in FIG. 3B, comprises crude TCS which exits the unit 340 via conduit 342 and enters a TCS refining unit 350. Within the TCS refining unit 350, TCS is separated from other materials, primarily STC, so as to provide a refined TCS stream which exits the TCS refining unit 350 via conduit 352. The refined TCS stream may be delivered to the CVD reactor 330 where it serves as a feedstock in polysilicon production. In addition, a product stream comprising STC may exit the TCS refining unit 350 via a conduit 354, and is directed back to the off-gas recovery system 371. Alternatively, and not shown in FIG. 3, the conduit 354 may lead to the chlorination reactor 300 in order to deliver STC coolant to the reactor 300, where the STC coolant may optionally pass through a temperature control unit (e.g., a heat exchanger or a chiller) prior to entering the reactor 300, so that the STC coolant is at a temperature which is less than the operating temperature of the reactor 300. Turning back to the product streams from the reactor off-gas recovery unit 340, another optional product stream, which is shown in FIG. 3B, comprises hydrogen which exits the unit 340 via conduit 344 and ultimately enters the chlorinator reactor 300. Optionally, the hydrogen in conduit 344 may be delivered into a hydrogen compressor 360 before it is delivered to the chlorinator 300. Yet one other optional product stream from reactor off-gas recovery unit 340 is a higher boiler purge which exits the unit 340 via conduit 346. The higher boiler purge comprises materials having a higher boiling point than STC, and is essentially a mixture of waste materials. The higher boiler purge may be sent to a waste treatment facility, not shown in FIG. 3.

The present disclosure provides, in one embodiment, a system comprising a chlorination reactor in fluid communication with a source of MGSi and also in fluid communication with a source of hydrogen chloride, the chlorination reactor also in fluid communication with at least one of a source of hydrogen and a source of STC. The hydrogen and/or STC provide the coolant of the present disclosure which allows the chlorination reaction taking place within the chlorinator to be performed in an adiabatic manner. In various optional embodiments, where any two or more of the following embodiments may be combined to describe an embodiment of the invention (so long as the embodiments are not mutually exclusive): the chlorination reactor is also in fluid communication with an STC converter, and the STC converter provides the source of STC (an STC converter is typically far from 100% efficient in converting STC to TCS, and accordingly the effluent from an STC converter will typically contain STC); the chlorination reactor is not in direct fluid communication with an STC converter, i.e., the effluent from an STC converter is not directly fed into the chlorination reactor, however, an STC converter may be present elsewhere in the system, e.g., an STC converter may be used to treat the STC that is present in the off gas from a CVD reactor that produces polysilicon by the Siemens process, in which case the product from this STC converter is not directly fed into the chlorinator but instead is fed into an off gas recovery system which generates a fraction enriched in STC which may be used as the source of STC in the chlorination reaction; the chlorination reactor is in fluid communication with a fractionation column, and an effluent from the fractionation column provides the source of STC, where this may occur, as mentioned previously, when the CVD reactor is in fluid communication with an STC converter, and the STC converter is in fluid communication with an off gas recovery system that includes a fractionation column; the system further comprises an off gas recovery system in fluid communication with the chlorination reactor, the off gas recovery system providing separation of components of off gas from the chlorination reactor, the off gas recovery system providing an off gas fraction enriched in hydrogen where at least some of the off gas fraction enriched in hydrogen provides the source of hydrogen to the chlorination reactor, in other words, the hydrogen present in the off gas from the chlorination reactor is recycled back into the chlorination reactor after having pass through an off gas recovery system that provides a fraction enriched in hydrogen; the chlorination reactor is a direct chlorination reactor which reacts hydrogen chloride with MGSi in a fluidized bed to produce ICS; the chlorination reactor in not in direct fluid communication with a STC converter such that the effluent from an STC converter is not directly introduced into the chlorination reactor; the system further comprises a source of STC in fluid communication with the chlorination reactor, whereby STC is introduced into the chlorination reactor along with hydrogen chloride and MGSi; the system further comprises a source of hydrogen in fluid communication with the chlorination reactor, whereby hydrogen is introduced into the chlorination reactor along with hydrogen chloride and MGSi; the system further comprises a chemical vapor deposition (CVD) reactor for producing polysilicon and a CVD off gas.

In a related embodiment, the present disclosure provides a process comprising a) performing a chlorination reaction in a chlorination reactor at a first temperature, where MGSi and hydrogen chloride are reacted together to provide a product gas comprising trichlorosilane; b) introducing a coolant selected from hydrogen and STC to the chlorination reactor, the coolant being introduced at a second temperature, the second temperature being less than the first temperature, the second temperature selected so that the chlorination reactor is performed under adiabatic conditions. In various optional embodiments, where any two or more of the following embodiments may be combined to describe an embodiment of the invention (so long as the embodiments are not mutually exclusive): the chlorination reactor is in fluid communication with an STC converter, and the STC converter provides the source of STC; the chlorination reactor is not in direct fluid communication with an STC converter; the chlorination reactor is in fluid communication with an off gas recovery system, where the off gas recovery system generates a fraction enriched in STC, and the fraction enriched in STC is introduced into the chlorination reactor to provide the source of STC to the chlorination reactor; an effluent from an STC converter is not directly introduced into the chlorination reactor; STC is introduced into the chlorination reactor along with hydrogen chloride and MGSi; the chlorination reactor is in fluid communication with an off gas recovery system, where the off gas recovery system generates a fraction enriched in hydrogen, and the fraction enriched in hydrogen is introduced into the chlorination reactor to provide the source of hydrogen to the chlorination reactor; the process further comprises performing the Siemens process for polysilcion production.

In one aspect, the present disclosure provides a chlorination process where the temperature of the gaseous reactor product, i.e., the gas product formed inside the reactor where the chlorination process takes place, is substantially controlled by controlling the temperature and composition of the gaseous feedstock(s) that comprise a chloride donor, particularly in the case where the reactor contains a molar excess of chloride acceptor, for example MGSi. Optionally: the gaseous feedstock comprises hydrogen and STC; the feedstock comprises hydrogen and TCS; the feedstock comprises hydrogen and HCl; the feedstock comprises STC and ICS; and/or the feedstock comprises hydrogen, STC, TCS, and HCl. In addition, and also optionally, the chlorination reactor is operated in an adiabatic mode and further optionally the reactor has no provision for heat removal by means of cooling surfaces internal or external to the reactor surface itself, e.g., the reactor has no internal or external cooling coils, or external cooling jacket or jackets on the shell. In addition, and also optionally, the feedstock to the chlorination reactor comes in whole or in part from an STC converter, wherein various embodiments, that portion of the feedstock coming from an STC converter comprises hydrogen, STC, TCS, and HCl; where the STC converter and chlorination reactor are in fluid communication with off-gas recovery equipment and hydrogen recycle equipment.

As described herein, one aspect of the present disclosure is a two-step process: (a) in a 1st stage reactor, referred to as an STC Converter, STC is converted to HCl and TCS in the presence of hydrogen gas; (b) in a 2nd stage reactor, the gaseous product of the 1st reactor is fed to a direct chlorination reactor where the HCl formed in the 1st stage reacts with metallurgic silicon to produce TCS. The STC converter may operate at low temperature, catalytic, non-equilibrium conditions. Viewed as a combined process, the feed to and the product exiting the system is identical to the feed to and products exiting a hydrochlorination reactor. However, the high pressure, high temperature, and high hold-up time required by a traditional hydrochlorination reactor are eliminated because the 2nd stage direct chlorination step runs at low pressure (i.e., 3 to 10 barg) and low temperature (e.g., 320 C), and because the direct chlorination reaction is relatively fast.

By lowering the temperature of the product leaving the 1st stage reactor to about 100-220° C., or about 200-210° C., e.g., 205° C., the 2nd stage reactor can be run as an adiabatic reactor. This is advantageous for the following reasons:

All external (e.g., cooling shell and/or cooling coil) heat transfer can be eliminated from the system which will greatly simplify design and operation, and reduce maintenance. (The cooling requirement associated with current generation direct chlorination reactors limits ease of scale-up and is a maintenance head-ache.)

The chlorination reactor of the present disclosure can be easily scaled up to large size, for example, the reactor may have a 3 meter to 4 meter diameter, capable of producing enough crude TCS to support 10,000 MTA polysilicon production.

By operating the 1st stage reactor to provide a product with a temperature of about 185° C., the heat capacity of the products exiting the 1st stage reactor and the mass of the material present in the 1st stage product combine to absorb the heat of the 2nd stage chlorination reaction, thereby limiting the temperature rise in the 2nd stage reactor. As a result, and in the absence of external cooling means, the 2nd stage reactor provides product that exits at about 320° C. As a side benefit, the larger flow rate into the 2nd stage chlorination reactor (approximately one order of magnitude greater molar flow rate compared to a convention HCl only chlorination reactor) eliminates hot spots within the reactor and by-products due to over-chlorination.

In the absence of either external cooling or internal cooling, the adiabatic temperature rise is so great that the chlorination process would be unworkable at best and dangerously unsafe at worst. For example, without heat removal either through the walls of the direct chlorination reactor or into internal coils filled with cooling medium, the adiabatic temperature rise due to HCl chlorination would increase the reactor temperature to 1790° C. This is unworkable because above 400° C. in such a system the chlorination reaction principally produces STC—not TCS. Since STC is an undesired by-product, this system is uneconomic. However, such a system would be dangerously unsafe to operate because the materials of construction—even if Inconel 800 H is used—it cannot withstand this high a temperature and the reaction vessel would catastrophically fail. The present process provide a process that utilizes internal cooling in order to safely operate the process and avoid the capital and maintenance expense associated with cooling coils and cooling jackets.

By including coolant in the feed to a chlorination reactor, in controlled amounts relative to HCl content, the coolant comprising one or more of hydrogen, STC, and TCS, in a molar ratio ranging from 2:1 coolant to HCl to 15:1 coolant to HCl, for example; or 3:1 to 5:1, or 5:1 to 7:1, or 8:1 to 10:1, and by cooling the feed to temperatures ranging from 100° C. to 300° C., or from 130° C. to 270° C., or from 150° C. to 250° C., or from 180° C. to 230° C., the chlorination reactor may be operated an adiabatic mode at desired operating temperatures ranging from 250° C. to 400° C., or from 300° C. to 350° C.

The present disclosure provides the following specific embodiments, which are not limiting on the invention, but are exemplary of the embodiments disclosed herein.
1) A process comprising:
   a. providing a reactor sited in an environment, the reactor comprising a reactor shell enclosing reactor contents;
   b. operating the reactor in a continuous mode at an operating temperature and an operating pressure;
   c. introducing gas phase HCl to the reactor under input conditions;
   d. introducing gas phase coolant to the reactor under input conditions comprising a coolant temperature less than the operating temperature;
   e. introducing MGSi to the reactor under input conditions;
   f. transferring chloride from HCl to MGSi within the reactor, the transfer being exothermic and generating heat within the reactor; and
   g. recovering a gas phase product comprising TCS exiting the reactor under exit conditions.
2) The process of embodiment 1 wherein the gas phase coolant comprises at least one of hydrogen, STC, TCS and DCS.
3) The process of embodiment 1 wherein the gas phase coolant comprises STC and hydrogen.
4) The process of embodiment 1 wherein HCl is in combination with the gas phase coolant upon introduction to the reactor.
5) The process of embodiment 1 wherein the reactor operating temperature is within the range of 250° C. to 450° C.
6) The process of embodiment 1 wherein the operating pressure is within the range of 1 barg to 15 barg.
7) The process of embodiment 1 wherein the HCl and the coolant enter the reactor at a molar ratio of coolant:HCl of 2:1 to 20:1.
8) The process of embodiment 1 wherein the chloride donor and the coolant are in admixture upon being introduced into the reactor, the admixture having a temperate within the range of 100-280° C. and being at least 30° C. less than the operating temperature of the reactor, the operating temperature of the reaction being a temperature within the range of 250-400° C. and the operating pressure being 1-15 barg, the admixture having a molar ratio of coolant:HCl of 2:1 to 20:1, the composition and temperature of the admixture selected so as to maintain the operating conditions within the reactor at a steady state.
9) The process of embodiment 1 wherein the heat is not transmitted to a cooling coil or a cooling jacket.
10) The process of embodiment 1 which is operated under adiabatic conditions.
11) The process of embodiment 1 wherein the input conditions for the HCl and the input conditions for the gas phase coolant comprise a temperature selected to maintain the reactor operating temperature within desired range.
12) The process of embodiment 1 further comprising:
   a. providing an STC converter;
   b. delivering STC and hydrogen to the STC converter;
   c. recovering an off gas comprising HCl and TCS from the STC converter;
   d. providing the off gas in unrefined form to the reactor to thereby provide at least a portion of the chloride donor and the coolant.
13) The process of embodiment 12 wherein the off gas recovered from the STC converter further comprises STC.
14) The process of embodiment 12 wherein HCl is added to the off gas prior to the off gas being provided in unrefined form to the reactor.
15) The process of embodiment 12 further comprising:
   a. introducing the product gas of step g) to an off gas recovery system whereby TCS is separated from hydrogen;
   b. introducing at least a portion of the hydrogen from step l) to a hydrogen compressor to provide compressed hydrogen;
   c. introducing at least a portion of the compressed hydrogen from step m) to the STC converter.
16) A system comprising:
   a. a 1^{st} stage reactor into which STC and hydrogen are introduced and a first product gas comprising TCS and HCl is recovered; and
   b. a 2^{nd} stage reactor in fluid communication with the 1^{st} stage reactor, where the first product gas and MGSi are introduced into the 2^{nd} stage reactor and a second product gas comprising hydrogen and TCS is recovered from the 2^{nd} stage reactor;
wherein the 1^{st} stage reactor delivers unrefined first product gas to the 2^{nd} stage reactor.
17) The system of embodiment 16 wherein the 1st stage reactor is an isothermal reactor.
18) The system of embodiment 16 wherein the 1st stage reactor is an adiabatic reactor.
19) The system of embodiment 16 further comprising an HCl source, where the HCl source is in fluid communication with a conduit in fluid communication with both the 1st stage reactor and the 2nd stage reactor.
20) The system of embodiment 16 further comprising a temperature control means to control the temperature of the first product gas before it enters the 2^{nd} stage reactor.
21) The system of embodiment 16 further comprising a temperature monitoring means to monitor the temperature within the 2^{nd} stage reactor.
22) The system of embodiment 16 where the temperature of the first product gas is adjusted to comprise a temperature selected to maintain the reactor 2^{nd} stage reactor operating temperature with the desired range.
23) The system of embodiment 16 further comprising a reactor where polysilicon may be prepared from TCS.
24) The system of embodiment 16 further comprising an off gas recovery system in fluid communication with the 2nd stage reactor which may separate TCS from hydrogen.
25) The system of embodiment 24 wherein the off gas recovery system in fluid communication with the 2^{nd} stage reactor is also in fluid communication with a hydrogen compressor, where the hydrogen compressor may compress the hydrogen separated by the off gas recovery system.
26) A system comprising a chlorination reactor in fluid communication with a source of MGSi and also in fluid communication with a source of hydrogen chloride, the chlorination reactor also in fluid communication with at least one of a source of hydrogen and a source of STC.
27) The system of embodiment 26 wherein the chlorination reactor is also in fluid communication with an STC converter, and the STC converter provides the source of STC.
28) The system of embodiment 26 wherein the chlorination reactor is not in direct fluid communication with an STC converter.
29) The system of embodiment 26 or 28, wherein the chlorination reactor is in fluid communication with a fractionation column, and an effluent from the fractionation column provides the source of STC.
30) The system of embodiment 26 further comprising an off gas recovery system in fluid communication with the chlorination reactor, the off gas recovery system providing separation of components of off gas from the chlorination reactor, the off gas recovery system providing an off gas fraction enriched in hydrogen where at least some of the off gas fraction enriched in hydrogen provides the source of hydrogen to the chlorination reactor.
31) The system of embodiment 26 wherein the chlorination reactor is a direct chlorination reactor which reacts hydrogen chloride with MGSi in a fluidized bed to produce TCS.
32) The system of embodiment 26 wherein the effluent from an STC converter is not directly introduced into the chlorination reactor.
33) The system of embodiment 26 comprising a source of STC in fluid communication with the chlorination reactor, whereby STC is introduced into the chlorination reactor along with hydrogen chloride and MGSi.
34) The system of embodiment 26 further comprising a chemical vapor deposition (CVD) reactor for producing polysilicon and a CVD off gas.
35) A process comprising a) performing a chlorination reaction in a chlorination reactor at a first temperature, where MGSi and hydrogen chloride are reacted together to provide a product gas comprising trichlorosilane; b) introducing a coolant selected from hydrogen and STC to the chlorination reactor, the coolant being introduced at a second temperature, the second temperature being less than the first temperature, the second temperature selected so that the chlorination reactor is performed under adiabatic conditions.
36) The process of embodiment 26 wherein the chlorination reactor is in fluid communication with an STC converter, and the STC converter provides the source of STC.
37) The process of embodiment 26 wherein the chlorination reactor is not in direct fluid communication with an STC converter.
38) The process of embodiment 26 or 28, wherein the chlorination reactor is in fluid communication with an off gas recovery system, where the off gas recovery system generates a fraction enriched in STC, and the fraction enriched in STC is introduced into the chlorination reactor to provide the source of STC to the chlorination reactor.
39) The process of embodiment 26 wherein an effluent from an STC converter is not directly introduced into the chlorination reactor.
40) The process of embodiment 26 wherein STC is introduced into the chlorination reactor along with hydrogen chloride and MGSi.
41) The process of embodiment 26 further wherein the chlorination reactor is in fluid communication with an off gas recovery system, where the off gas recovery system generates a fraction enriched in hydrogen, and the fraction enriched in hydrogen is introduced into the chlorination reactor to provide the source of hydrogen to the chlorination reactor.
42) The process of embodiment 26 further comprising producing polysilicon.

All of the U.S. patents, U.S. patent application publications, U.S. patent applications, foreign patents, foreign patent applications and non-patent publications referred to in this specification and/or listed in the Application Data Sheet, if any, are incorporated herein by reference, in their entirety. The processes and systems for non-equilibrium trichlorosilane production as disclosed in PCT/US2012/064,568 (published as WO 2013/074425), and as disclosed in U.S. Application No. 61/559,657, are each optionally incorporated herein by reference.

Any of the various embodiments described above can be combined to provide further embodiments. Aspects of the embodiments can be modified, if necessary to employ concepts of the various patents, applications and publications to provide yet further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A process comprising:
a) providing a reactor sited in an environment, the reactor comprising a reactor shell enclosing reactor contents;
b) operating the reactor in a continuous mode at an operating temperature and an operating pressure;
c) introducing gas phase HCl to the reactor under input conditions;
d) introducing gas phase coolant to the reactor under input conditions comprising a coolant temperature less than the operating temperature;
e) introducing MGSi to the reactor under input conditions;
f) transferring chloride from HCl to MGSi within the reactor, the transfer being exothermic and generating heat within the reactor; and
g) recovering a gas phase product comprising TCS exiting the reactor under exit conditions.

2. The process of claim 1 wherein the gas phase coolant comprises at least one of hydrogen, STC, TCS and DCS.

3. The process of claim 1 wherein the gas phase coolant comprises STC and hydrogen.

4. The process of claim 1 wherein the reactor operating temperature is within the range of 250° C. to 450° C.

5. The process of claim 1 wherein the operating pressure is within the range of 1 barg to 15 barg.

6. The process of claim 1 wherein the chloride donor and the coolant are in admixture upon being introduced into the reactor, the admixture having a temperate within the range of 100-280° C. and being at least 30° C. less than the operating temperature of the reactor, the operating temperature of the reaction being a temperature within the range of 250-400° C. and the operating pressure being 1-15 barg, the admixture having a molar ratio of coolant:HCl of 2:1 to 20:1, the composition and temperature of the admixture selected so as to maintain the operating conditions within the reactor at a steady state.

7. The process of claim 1 which is operated under adiabatic conditions.

8. The process of claim 1 further comprising:
h) providing an STC converter;
i) delivering STC and hydrogen to the STC converter;
j) recovering an off gas comprising HCl and TCS from the STC converter;
k) providing the off gas in unrefined form to the reactor to thereby provide at least a portion of the chloride donor and the coolant.

9. The process of claim 8 further comprising:
l) introducing the product gas of step g) to an off gas recovery system whereby TCS is separated from hydrogen;
m) introducing at least a portion of the hydrogen from step l) to a hydrogen compressor to provide compressed hydrogen;
n) introducing at least a portion of the compressed hydrogen from step m) to the STC converter.

10. A system comprising:
a) a 1^{st} stage reactor into which STC and hydrogen are introduced and a first product gas comprising TCS and HCl is recovered; and
b) a 2^{nd} stage reactor in fluid communication with the 1^{st} stage reactor, where the first product gas and MGSi are introduced into the 2^{nd} stage reactor and a second product gas comprising hydrogen and TCS is recovered from the 2^{nd} stage reactor;
wherein the 1^{st} stage reactor delivers unrefined first product gas to the 2^{nd} stage reactor.

11. The system of claim 10 wherein the 1st stage reactor is an isothermal reactor.

12. The system of claim 10 wherein the 1st stage reactor is an adiabatic reactor.

13. A system comprising a chlorination reactor in fluid communication with a source of MGSi and also in fluid communication with a source of hydrogen chloride, the chlorination reactor also in fluid communication with at least one of a source of hydrogen and a source of STC.

14. The system of embodiment claim 13 further comprising a chemical vapor deposition (CVD) reactor for producing polysilicon and a CVD off gas.

15. A process comprising a) performing a chlorination reaction in a chlorination reactor at a first temperature, where MGSi and hydrogen chloride are reacted together to provide a product gas comprising trichlorosilane; b) introducing a coolant selected from hydrogen and STC to the chlorination reactor, the coolant being introduced at a second temperature, the second temperature being less than the first temperature, the second temperature selected so that the chlorination reactor is performed under adiabatic conditions.
